(19) United States
(12) Patent Application Publication
(10) Pub. No.: US 2026/0371712 A1
(43) Pub. Date: Nov. 19, 2026

(54) SEMICONDUCTOR DEVICE WITH NANOSHEETS

(71) Applicant: Samsung Electronics Co., Ltd., Suwon-si (KR)

(72) Inventors: Won Hyuk LEE, Suwon-si (KR); Da Eun BAN, Suwon-si (KR); Yeon Jung OH, Suwon-si (KR); Jang Geun LEE, Suwon-si (KR); Jong Sun LEE, Suwon-si (KR); Cheol In JANG, Suwon-si (KR)

(21) Appl. No.: 19/429,615

(22) Filed: Dec. 22, 2025

(30) Foreign Application Priority Data
May 13, 2025 (KR) 10-2025-0061754

(51) Int. Cl. H10D 84/83; H10D 84/01

(52) U.S. Cl. CPC H10D 84/833; H10D 84/0151

(57) ABSTRACT

A semiconductor device includes a substrate, a first and second active patterns extending in a first horizontal direction on the substrate, the second active pattern spaced apart from the first active pattern in a second horizontal direction, a field insulating layer surrounding each of the first and the second active patterns on the substrate, a first and second plurality of nanosheets on an upper surface of the first and second active pattern, respectively, and a first channel isolation layer extending in the first horizontal direction between the first and the second active patterns and in contact with a sidewall of each of the first and the second plurality of nanosheets, a lower surface of the first channel isolation layer formed lower than an upper surface of the field insulating layer.

### CROSS-REFERENCE TO RELATED APPLICATION

This application claims benefit of priority under 35 U.S.C. § 119 to Korean Patent Application No. 10-2025-0061754 filed on May 13, 2025, in the Korean Intellectual Property Office, the contents of which are incorporated by reference herein in their entirety.

### BACKGROUND

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, scaling is facilitated. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure relates to a semiconductor device. More particularly, the present disclosure relates to a semiconductor device including a MBCFET^{TM} (Multi-Bridge Channel Field Effect Transistor).

The present disclosure aims to provide a semiconductor device and a method for fabricating the same, which may improve reliability by forming a channel isolation layer that separates each of a plurality of nanosheets and active patterns in a horizontal direction as a multi-layer structure including different materials, thereby preventing excessive etching of the channel isolation layer.

The aspects of the present disclosure are not limited to those mentioned above, and other aspects that are not explicitly described may be clearly understood by those skilled in the art from the following description.

According to some implementations of the present disclosure, there is provided a semiconductor device, comprising a substrate, a first active pattern extending in a first horizontal direction on the substrate, a second active pattern extending in the first horizontal direction on the substrate, the second active pattern spaced apart from the first active pattern in a second horizontal direction different from the first horizontal direction, a field insulating layer surrounding each of the first and the second active patterns on the substrate, a first plurality of nanosheets spaced apart from each other in a vertical direction and stacked on an upper surface of the first active pattern, a second plurality of nanosheets spaced apart from each other in the vertical direction and stacked on an upper surface of the second active pattern, the second plurality of nanosheets spaced apart from the first plurality of nanosheets in the second horizontal direction, and a first channel isolation layer extending in the first horizontal direction between the first and the second active patterns, the first channel isolation layer being in contact with a sidewall of each of the first and the second plurality of nanosheets, a lower surface of the first channel isolation layer formed lower than an upper surface of the field insulating layer, wherein the first channel isolation layer comprises a first layer being in contact with a sidewall of the first and the second active patterns and the sidewall of each of the first and the second plurality of nanosheets, the first layer forming a lower surface and sidewalls of the first channel isolation layer, and a second layer surrounded by the first layer, a material of the second layer different from a material of the first layer.

According to some implementations of the present disclosure, there is provided a semiconductor device, comprising a substrate, a first active pattern extending in a first horizontal direction on the substrate, a second active pattern extending in the first horizontal direction on the substrate, the second active pattern spaced apart from the first active pattern in a second horizontal direction different from the first horizontal direction, a first plurality of nanosheets spaced apart from each other in a vertical direction and stacked on an upper surface of the first active pattern, a second plurality of nanosheets spaced apart from each other in the vertical direction and stacked on an upper surface of the second active pattern, the second plurality of nanosheets spaced apart from the first plurality of nanosheets in the second horizontal direction, a channel isolation layer extending in the first horizontal direction between the first and second active patterns, the channel isolation layer being in contact with a sidewall of each of the first and second plurality of nanosheets, a gate electrode extending in the second horizontal direction on the upper surfaces of the first and second active patterns, the gate electrode surrounding the first and second plurality of nanosheets, and a gate insulating layer disposed between the gate electrode and the first plurality of nanosheets and between the gate electrode and the channel isolation layer, the gate insulating layer not disposed between a lowermost nanosheet of the first plurality of nanosheets and the channel isolation layer, wherein the channel isolation layer comprises a first layer being in contact with a sidewall of each of the first and second active patterns and the sidewall of each of the first and second plurality of nanosheets, the first layer forming a lower surface and sidewalls of the channel isolation layer, and a second layer surrounded by the first layer, a material of the second layer a material different from a material of first layer.

According to some implementations of the present disclosure, there is provided a semiconductor device, comprising a substrate, a first active pattern extending in a first horizontal direction on the substrate, a second active pattern extending in the first horizontal direction on the substrate, the second active pattern spaced apart from the first active pattern in a second horizontal direction different from the first horizontal direction, a third active pattern extending in the first horizontal direction on the substrate, the third active pattern spaced apart from the first active pattern in the second horizontal direction, the third active pattern spaced apart from the second active pattern in the first horizontal direction, a first plurality of nanosheets spaced apart from each other in a vertical direction and stacked on an upper surface of the first active pattern, a second plurality of nanosheets spaced apart from each other in the vertical direction and stacked on an upper surface of the second active pattern, the second plurality of nanosheets spaced apart from the first plurality of nanosheets in the second horizontal direction, a third plurality of nanosheets spaced apart from each other in the vertical direction and stacked on the upper surface of the first active pattern, the third plurality of nanosheets spaced apart from the first plurality of nanosheets in the first horizontal direction, a fourth plurality of nanosheets spaced apart from each other in the vertical direction and stacked on an upper surface of the third active pattern, the fourth plurality of nanosheets spaced apart from the second plurality of nanosheets in the first horizontal direction, the fourth plurality of nanosheets spaced apart from the third plurality of nanosheets in the second horizontal direction, a first channel isolation layer extending in the first horizontal direction between the first and second active patterns, the first channel isolation layer being in contact with a sidewall of each of the first and second plurality of nanosheets, a second channel isolation layer extending in the first horizontal direction between the first and third active patterns, the second channel isolation layer spaced apart from the first channel isolation layer in the first horizontal direction, a first gate electrode extending in the second horizontal direction on the first and second active patterns, the first gate electrode surrounding the first and second plurality of nanosheets, and a second gate electrode extending in the second horizontal direction on the first and third active patterns, the second gate electrode surrounding the third and fourth plurality of nanosheets, the second gate electrode spaced apart from the first gate electrode in the first horizontal direction, wherein the first channel isolation layer comprises a first layer being in contact with a sidewall of each of the first and second active patterns and the sidewall of each of the first and second plurality of nanosheets, the first layer forming a lower surface and sidewalls of the first channel isolation layer, and a second layer surrounded by the first layer, a material of the second layer different from a material of the first layer.

### BRIEF DESCRIPTION OF THE DRAWINGS

The above and other aspects and features of the present disclosure will become more apparent by describing in detail exemplary implementations thereof with reference to the attached drawings, in which:

FIG. 1 is a layout diagram for explaining a semiconductor device according to some implementations of the present disclosure;

FIG. 2 is a cross-sectional view taken along line A-A' of FIG. 1;

FIG. 3 is a cross-sectional view taken along line B-B' of FIG. 1;

FIG. 4 is a cross-sectional view taken along line C-C' of FIG. 1;

FIG. 5 is a cross-sectional view taken along line D-D' of FIG. 1;

FIGS. 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, and 51 are intermediate stage diagrams for explaining a method for fabricating a semiconductor device according to some implementations of the present disclosure;

FIG. 52 is a cross-sectional view for explaining a semiconductor device according some implementations of the present disclosure; and

FIG. 53 is a cross-sectional view for explaining a semiconductor device according to some implementations of the present disclosure.

### DETAILED DESCRIPTION

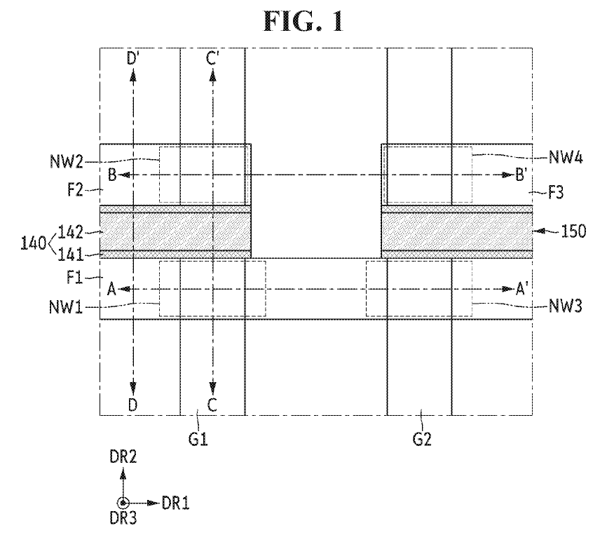

Hereinafter, a semiconductor device according to some implementations of the present disclosure will be described with reference to FIGS. 1-5.

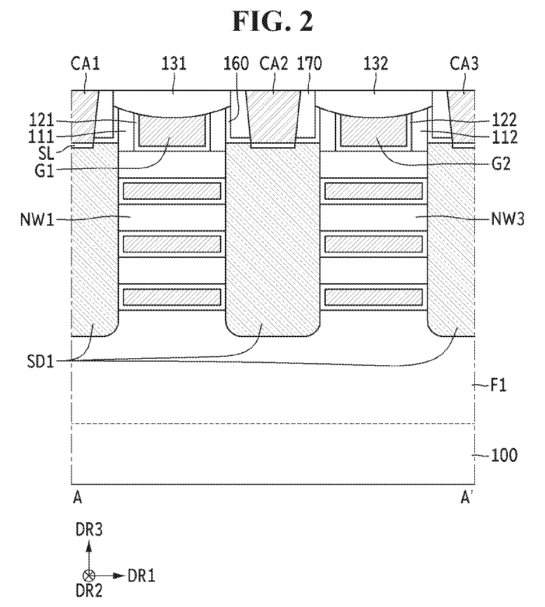

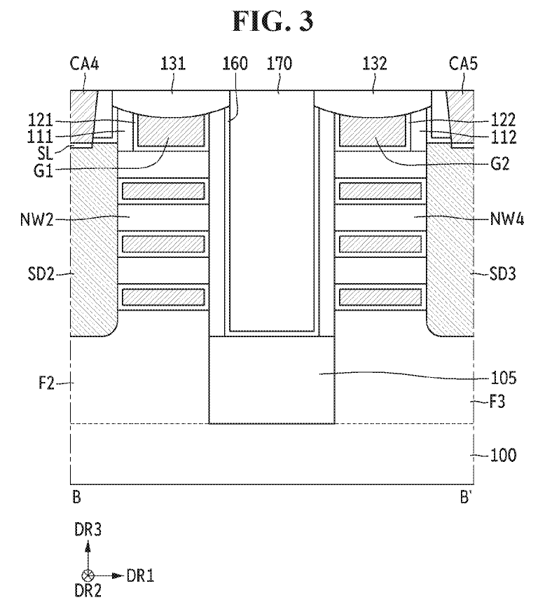

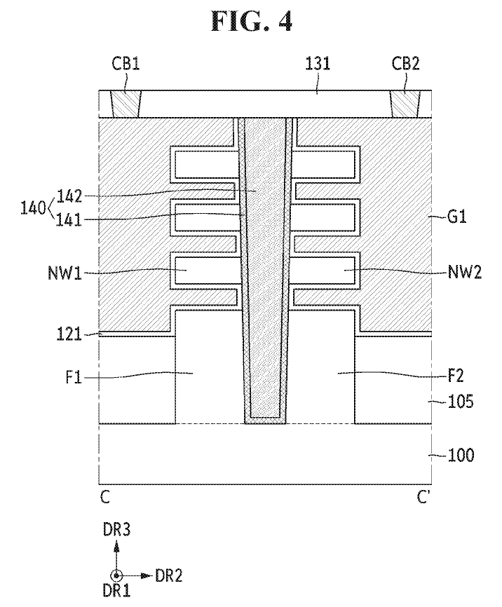

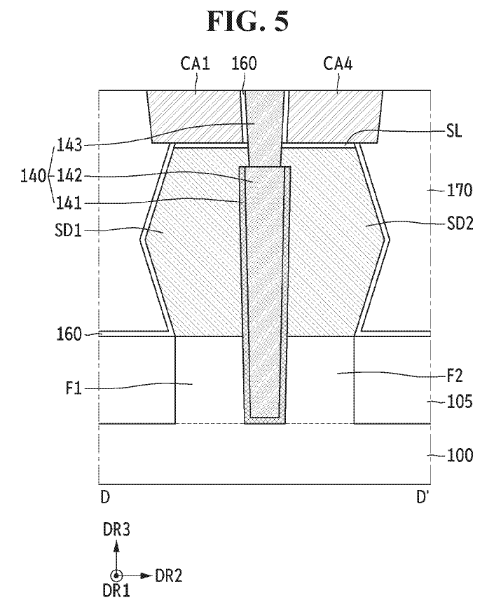

FIG. 1 is a layout diagram for explaining a semiconductor device according to some implementations of the present disclosure. FIG. 2 is a cross-sectional view taken along line A-A' of FIG. 1. FIG. 3 is a cross-sectional view taken along line B-B' of FIG. 1. FIG. 4 is a cross-sectional view taken along line C-C' of FIG. 1. FIG. 5 is a cross-sectional view taken along line D-D' of FIG. 1.

Referring to FIGS. 1-5, a semiconductor device according to some implementations of the present disclosure may include a substrate 100, first to third active patterns F1, F2, F3, a field insulating layer 105, a plurality of first to fourth nanosheets NW1 to NW4, first and second gate electrodes G1, G2, first and second gate spacers 111, 112, first and second gate insulating layers 121, 122, first and second capping patterns 131, 132, a first channel isolation layer 140, a second channel isolation layer 150, first to third source/drain regions SD1, SD2, SD3, an etching stop layer 160, an interlayer insulating layer 170, first to fifth source/drain contacts CA1 to CA5, a silicide layer SL, and first and second gate contacts CB1, CB2.

The substrate 100 may be a silicon substrate or a silicon-on-insulator (SOI) substrate. Alternatively, the substrate 100 may include silicon germanium, silicon germanium on insulator (SGOI), indium antimonide, lead telluride compounds, indium arsenide, indium phosphide, gallium arsenide, or gallium antimonide. However, the present disclosure is not limited thereto. Hereinafter, a first horizontal direction DR1 and a second horizontal direction DR2 may be defined as directions parallel to an upper surface of the substrate 100.

The second horizontal direction DR2 may be defined as a direction different from the first horizontal direction DR1. A vertical direction DR3 may be defined as a direction perpendicular to both the first horizontal direction DR1 and the second horizontal direction DR2. That is, the vertical direction DR3 may be defined as a direction perpendicular to the upper surface of the substrate 100.

Each of the first active pattern F1, the second active pattern F2, and the third active pattern F3 may extend in the first horizontal direction DR1 on an upper surface of the substrate 100. The second active pattern F2 may be spaced apart from the first active pattern F1 in the second horizontal direction DR2. The third active pattern F3 may be spaced apart from the first active pattern F1 in the second horizontal direction DR2. The third active pattern F3 may be spaced apart from the second active pattern F2 in the first horizontal direction DR1. Each of the first to third active patterns F1, F2, F3 may protrude from the upper surface of the substrate 100 in the vertical direction DR3. For example, each of the first to third active patterns F1, F2, F3 may be part of the substrate 100 or may include an epitaxial layer grown from the substrate 100. For example, the first active pattern F1 and the second active pattern F2 may be separated in the second horizontal direction DR2 by the first channel isolation layer 140, which will be described later. In addition, the first active pattern F1 and the third active pattern F3 may be separated in the second horizontal direction DR2 by a second channel isolation layer 150, which will also be described later.

The field insulating layer 105 may be disposed on the upper surface of the substrate 100. The field insulating layer 105 may surround sidewalls of the first to third active patterns F1, F2, F3. For example, the upper surface of each of the first to third active patterns F1, F2, F3 may protrude in the vertical direction DR3 beyond the upper surface of the field insulating layer 105. However, the present disclosure is not limited thereto. In some implementations, the upper surface of each of the first to third active patterns F1, F2, F3 may be formed on the same plane as the upper surface of the field insulating layer 105. The field insulating layer 105 may include, for example, an oxide layer, a nitride layer, an oxynitride layer, or a combination thereof.

The first plurality of nanosheets NW1 may be disposed on the upper surface of the first active pattern F1. The first plurality of nanosheets NW1 may include a plurality of nanosheets spaced apart from each other in the vertical direction DR3 and stacked on the upper surface of the first active pattern F1. The second plurality of nanosheets NW2 may be disposed on the upper surface of the second active pattern F2. The second plurality of nanosheets NW2 may include a plurality of nanosheets spaced apart from each other in the vertical direction DR3 and stacked on the upper surface of the second active pattern F2. The second plurality of nanosheets NW2 may be spaced apart from the first plurality of nanosheets NW1 in the second horizontal direction DR2. The third plurality of nanosheets NW3 may be disposed on the upper surface of the first active pattern F1. The third plurality of nanosheets NW3 may include a plurality of nanosheets spaced apart from each other in the vertical direction DR3 and stacked on the upper surface of the first active pattern F1. The third plurality of nanosheets NW3 may be spaced apart from the first plurality of nanosheets NW1 in the first horizontal direction DR1. The fourth plurality of nanosheets NW4 may be disposed on the upper surface of the third active pattern F3. The fourth plurality of nanosheets NW4 may include a plurality of nanosheets spaced apart from each other in the vertical direction DR3 and stacked on the upper surface of the third active pattern F3. The fourth plurality of nanosheets NW4 may be spaced apart from the second plurality of nanosheets NW2 in the first horizontal direction DR1. The fourth plurality of nanosheets NW4 may be spaced apart from the third plurality of nanosheets NW3 in the second horizontal direction DR2.

For example, the width of the second plurality of nanosheets NW2 in the first horizontal direction DR1 may be smaller than the width of the first plurality of nanosheets NW1 in the first horizontal direction DR1. Also, the width of the fourth plurality of nanosheets NW4 in the first horizontal direction DR1 may be smaller than the width of the third plurality of nanosheets NW3 in the first horizontal direction DR1. In FIGS. 2-4, each of the first plurality of nanosheets NW1, the second plurality of nanosheets NW2, the third plurality of nanosheets NW3, and the fourth plurality of nanosheets NW4 is shown as including three nanosheets spaced apart from each other in the vertical direction DR3 and stacked, but the present disclosure is not limited thereto. In some implementations, each of the first plurality of nanosheets NW1, the second plurality of nanosheets NW2, the third plurality of nanosheets NW3, and the fourth plurality of nanosheets NW4 may include four or more nanosheets spaced apart from each other in the vertical direction DR3 and stacked. For example, each of the first plurality of nanosheets NW1 to the fourth plurality of nanosheetsvNW4 may include silicon (Si).

The first gate electrode G1 may extend in the second horizontal direction DR2 over the field insulating layer 105 and the first and second active patterns F1, F2. For example, the first gate electrode G1 may surround each of the first plurality of nanosheets NW1 and the second plurality of nanosheets NW2. The first gate electrode G1 may be separated in the second horizontal direction DR2 by the first channel isolation layer 140, which will be described later. However, the present disclosure is not limited thereto. The second gate electrode G2 may extend in the second horizontal direction DR2 over the field insulating layer 105 and the first and third active patterns F1, F3. For example, the second gate electrode G2 may surround each of the third plurality of nanosheets NW3 and the fourth plurality of nanosheets NW4. The second gate electrode G2 may be spaced apart from the first gate electrode G1 in the first horizontal direction DR1. The second gate electrode G2 may be separated in the second horizontal direction DR2 by a second channel isolation layer 150, which will be described later. However, the present disclosure is not limited thereto.

For example, each of the first and second gate electrodes G1, G2 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. Each of the first and second gate electrodes G1, G2 may include a conductive metal oxide, a conductive metal oxynitride, or the like, and may include an oxidized form of the aforementioned materials.

The first gate spacer 111 may be disposed on both sidewalls of the first gate electrode G1 in the first horizontal direction DR1. The first gate spacer 111 may extend in the second horizontal direction DR2 over the upper surface of uppermost nanosheets of each of the first and second plurality of nanosheets NW1, NW2, and over the field insulating layer 105. The second gate spacer 112 may be disposed on both sidewalls of the second gate electrode G2 in the first horizontal direction DR1. The second gate spacer 112 may extend in the second horizontal direction DR2 over the upper surface of uppermost nanosheets of each of the third and fourth plurality of nanosheets NW3, NW4, and over the field insulating layer 105. For example, each of the first and second gate spacers 111, 112 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), and a combination thereof. However, the present disclosure is not limited thereto.

The first source/drain region SD1 may be disposed on both sides of the first gate electrode G1 and the second gate electrode G2 in the first horizontal direction DR1 on the first active pattern F1. The second source/drain region SD2 may be disposed on one side of the second active pattern F2 in the first horizontal direction DR1. The third source/drain region SD3 may be disposed on one side of the third active pattern F3 in the first horizontal direction DR1. For example, the first source/drain region SD1 and the second source/drain region SD2 may be separated in the second horizontal direction DR2 by the first channel isolation layer 140, which will be described later. Although not shown, the first source/drain region SD1 and the third source/drain region SD3 may be separated in the second horizontal direction DR2 by the second channel isolation layer 150, which will be described later.

The first channel isolation layer 140 may be disposed between the first active pattern F1 and the second active pattern F2. The first channel isolation layer 140 may be disposed between the first plurality of nanosheets NW1 and the second plurality of nanosheets NW2. The first channel isolation layer 140 may be disposed between the first source/drain region SD1 and the second source/drain region SD2. The first channel isolation layer 140 may extend in the first horizontal direction DR1. The first channel isolation layer 140 may be in contact with the sidewall of each of the first and second active patterns F1, F2 in the second horizontal direction DR2. The first channel isolation layer 140 may be in contact with the sidewall of each of the first and second plurality of nanosheets NW1, NW2 in the second horizontal direction DR2. The first channel isolation layer 140 may be in contact with the sidewall of each of the first and second source/drain regions SD1, SD2 in the second horizontal direction DR2. For example, the lower surface of the first channel isolation layer 140 may be formed lower than the upper surface of the field insulating layer 105. For example, the lower surface of the first channel isolation layer 140 may be in contact with the upper surface of the substrate 100.

For example, the uppermost surface of the first channel isolation layer 140 may be formed higher, in relation to the substrate, than the upper surface of the uppermost nanosheets of each of the first and second plurality of nanosheets NW1, NW2. For example, the first channel isolation layer 140 may separate the first and second active patterns F1, F2 from each other in the second horizontal direction DR2. The first channel isolation layer 140 may separate the first and second plurality of nanosheets NW1, NW2 from each other in the second horizontal direction DR2. The first channel isolation layer 140 may separate the first and second source/drain regions SD1, SD2 from each other in the second horizontal direction DR2. The first channel isolation layer 140 may separate the first and second gate electrodes G1, G2 from each other in the second horizontal direction DR2. In FIG. 1, the sidewall of the first channel isolation layer 140 in the first horizontal direction DR1 is shown to be aligned in the second horizontal direction DR2 with the sidewall of the second active pattern F2 in the first horizontal direction DR1, but the present disclosure is not limited thereto.

For example, the first channel isolation layer 140 may include a first layer 141, a second layer 142, and a third layer 143. The first layer 141 may form a portion of sidewalls and the lower surface of the first channel isolation layer 140. For example, the first layer 141 may be conformally formed. For example, the first layer 141 may be in contact with the sidewall of each of the first and second active patterns F1, F2 in the second horizontal direction DR2. The first layer 141 may be in contact with the sidewall of each of the first and second plurality of nanosheets NW1, NW2 in the second horizontal direction DR2. The first layer 141 may be in contact with the sidewall of each of the first and second source/drain regions SD1, SD2 in the second horizontal direction DR2. For example, a lowermost surface of the first layer 141 may be in contact with the upper surface of the substrate 100, but the present disclosure is not limited thereto.

For example, an uppermost surface of the first layer 141 may be formed higher, in relation to the substrate, than the upper surface of uppermost nanosheets of each of the first plurality of nanosheets NW1 and the second plurality of nanosheets NW2. For example, the uppermost surface of the first layer 141 may be formed on the same plane as the upper surface of the first gate electrode G1. For example, between the first source/drain region SD1 and the second source/drain region SD2, the upper surface of the first layer 141 may be in contact with each of the first and second source/drain regions SD1, SD2. However, the present disclosure is not limited thereto. For example, the first layer 141 may include silicon oxycarbide (SiOC). In some other implementations, the first layer 141 may include any one of silicon carbonitride (SiCN) or silicon oxycarbonitride (SiOCN).

For example, the second layer 142 may be disposed between portions of the first layer 141. The second layer 142 may be surrounded by the first layer 141. For example, the second layer 142 may not be in contact with each of the first and second active patterns F1 and F2. That is, the second layer 142 may be spaced apart from each of the first and second active patterns F1 and F2 in the second horizontal direction DR2. For example, the second layer 142 may not be in contact with each of the first and second plurality of nanosheets NW1, NW2. That is, the second layer 142 may be spaced apart from each of the first and second plurality of nanosheets NW1, NW2 in the second horizontal direction DR2. For example, the second layer 142 may not be in contact with the upper surface of the substrate 100. That is, the second layer 142 may be spaced apart from the upper surface of the substrate 100 in the vertical direction DR3.

For example, an uppermost surface of the second layer 142 may be formed higher, in relation to the substrate, than the upper surface of uppermost nanosheets of each of the first and second plurality of nanosheets NW1, NW2. For example, the uppermost surface of the second layer 142 may be formed on the same plane as the uppermost surface of the first layer 141. For example, the uppermost surface of the second layer 142 may be formed on the same plane as the upper surface of the first gate electrode G1. For example, between the first source/drain region SD1 and the second source/drain region SD2, at least a portion of the upper surface of the second layer 142 may be in contact with each of the first and second source/drain regions SD1, SD2. However, the present disclosure is not limited thereto. For example, the second layer 142 may include a material different from that of the first layer 141. For example, the second layer 142 may include silicon nitride (SiN). However, the present disclosure is not limited thereto.

Between the first source/drain region SD1 and the second source/drain region SD2, the third layer 143 may be disposed on the upper surface of the second layer 142. For example, the lower surface of the third layer 143 may be in contact with the upper surface of the second layer 142. sidewalls of the third layer 143 in the second horizontal direction DR2 may be in contact with each of the first and second source/drain regions SD1, SD2. The third layer 143 may include an insulating material. For example, the third layer 143 may include silicon nitride (SiN). However, the present disclosure is not limited thereto.

The second channel isolation layer 150 may be disposed between the first active pattern F1 and the third active pattern F3. The second channel isolation layer 150 may be disposed between the third plurality of nanosheets NW3 and the fourth plurality of nanosheets NW4. The second channel isolation layer 150 may be disposed between the first source/drain region SD1 and the third source/drain region SD3. The second channel isolation layer 150 may be spaced apart from the first channel isolation layer 140 in the first horizontal direction DR1. The second channel isolation layer 150 may extend in the first horizontal direction DR1. The second channel isolation layer 150 may be in contact with the sidewall of each of the first and third active patterns F1, F3 in the second horizontal direction DR2. The second channel isolation layer 150 may be in contact with the sidewall of each of the third and fourth plurality of nanosheets NW3, NW4 in the second horizontal direction DR2. The second channel isolation layer 150 may be in contact with the sidewall of each of the first and third source/drain regions SD1, SD3 in the second horizontal direction DR2. For example, the shape of the second channel isolation layer 150 may be similar to that of the first channel isolation layer 140. Therefore, a detailed description of the second channel isolation layer 150 will be omitted.

The first gate insulating layer 121 may be disposed between the first gate electrode G1 and the first active pattern F1. The first gate insulating layer 121 may be disposed between the first gate electrode G1 and the second active pattern F2. The first gate insulating layer 121 may be disposed between the first gate electrode G1 and the field insulating layer 105. The first gate insulating layer 121 may be disposed between the first gate electrode G1 and the first plurality of nanosheets NW1. The first gate insulating layer 121 may be disposed between the first gate electrode G1 and the second plurality of nanosheets NW2. The first gate insulating layer 121 may be disposed between the first gate electrode G1 and the first channel isolation layer 140. That is, the first gate insulating layer 121 may be disposed between the first gate electrode G1 and the first layer 141 of the first channel isolation layer 140. The first gate insulating layer 121 may be disposed between the first gate electrode G1 and the first gate spacer 111. The first gate insulating layer 121 may be disposed between the first gate electrode G1 and the first source/drain region SD1. The first gate insulating layer 121 may be disposed between the first gate electrode G1 and the second source/drain region SD2.

For example, the first gate insulating layer 121 may not be in contact with the first gate electrode G1 and the second layer 142 of the first channel isolation layer 140. For example, the first gate insulating layer 121 may not be disposed (or absent) between the first layer 141 of the first channel isolation layer 140 and the first plurality of nanosheets NW1. The first gate insulating layer 121 may not be disposed (or absent) between the first layer 141 of the first channel isolation layer 140 and the second plurality of nanosheets NW2. For example, the first gate insulating layer 121 may not be disposed (or absent) between the lowermost nanosheet of each of the first and second plurality of nanosheets NW1, NW2 and the first layer 141 of the first channel isolation layer 140. In addition, the first gate insulating layer 121 may not be disposed (or absent) between the uppermost nanosheet of each of the first and second plurality of nanosheets NW1, NW2 and the first layer 141 of the first channel isolation layer 140.

The second gate insulating layer 122 may be disposed between the second gate electrode G2 and the first active pattern F1. The second gate insulating layer 122 may be disposed between the second gate electrode G2 and the third active pattern F3. The second gate insulating layer 122 may be disposed between the second gate electrode G2 and the field insulating layer 105. The second gate insulating layer 122 may be disposed between the second gate electrode G2 and the third plurality of nanosheets NW3. The second gate insulating layer 122 may be disposed between the second gate electrode G2 and the fourth plurality of nanosheets NW4. The second gate insulating layer 122 may be disposed between the second gate electrode G2 and the second channel isolation layer 150. The second gate insulating layer 122 may be disposed between the second gate electrode G2 and the second gate spacer 112. The second gate insulating layer 122 may be disposed between the second gate electrode G2 and the first source/drain region SD1. The second gate insulating layer 122 may be disposed between the second gate electrode G2 and the third source/drain region SD3.

Each of the first and second gate insulating layers 121, 122 may include at least one of silicon oxide, silicon oxynitride, silicon nitride, or a high-k dielectric material having a dielectric constant greater than that of silicon oxide. The high-k dielectric material may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other implementations may include an NC (Negative Capacitance) FET using a negative capacitor. For example, each of the first and second gate insulating layers 121, 122 may include a ferroelectric material layer having ferroelectric properties and a paraelectric material layer having paraelectric properties.

The ferroelectric material layer may have a negative capacitance, while the paraelectric material layer may have a positive capacitance. For example, when two or more capacitors are connected in series and the capacitance of each of the capacitors is positive, the total capacitance becomes less than that of each individual capacitor. On the other hand, if at least one of the capacitances of two or more capacitors connected in series is negative, the total capacitance may remain positive and be greater than the absolute value of each individual capacitance.

When the ferroelectric material layer having a negative capacitance is connected in series with the paraelectric material layer having a positive capacitance, the total capacitance value of the ferroelectric material layer and the paraelectric material layer connected in series may increase. By utilizing the increase in total capacitance value, the transistor including the ferroelectric material layer may have a subthreshold swing (SS) less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As an example, hafnium zirconium oxide may be a material in which zirconium (Zr) is doped into hafnium oxide. In another example, hafnium zirconium oxide may be a compound of hafnium (Hf) and zirconium (Zr) combined with oxygen (O).

The ferroelectric material layer may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material layer may vary depending on the ferroelectric material included therein.

For example, if the ferroelectric material layer includes hafnium oxide, the dopant included in the ferroelectric material layer may include at least one of gadolinium (Gd), silicon (Si), zirconium (Zr), aluminum (Al), and yttrium (Y).

If the dopant is aluminum (Al), the ferroelectric material layer may include about 3 to 8 at% (atomic %) of aluminum. In this case, the ratio of the dopant may be the ratio of aluminum to the sum of hafnium and aluminum.

If the dopant is silicon (Si), the ferroelectric material layer may include 2 to 10 at% of silicon. If the dopant is yttrium (Y), the ferroelectric material layer may include 2 to 10 at% of yttrium. If the dopant is gadolinium (Gd), the ferroelectric material layer may include 1 to 7 at% of gadolinium. If the dopant is zirconium (Zr), the ferroelectric material layer may include 50 to 80 at% of zirconium.

The paraelectric material layer may have paraelectric properties. The paraelectric material layer may include, for example, at least one or more of silicon oxide and a metal oxide having a high-k dielectric constant. The metal oxide included in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, if both the ferroelectric material layer and the paraelectric material layer include hafnium oxide, the crystal structure of the hafnium oxide included in the ferroelectric material layer may be different from the crystal structure of the hafnium oxide included in the paraelectric material layer.

The ferroelectric material layer may have a thickness that enables the ferroelectric properties. For example, the thickness of the ferroelectric material layer may range from 0.5 to 10 nm, but is not limited thereto. Since the critical thickness for exhibiting ferroelectric properties may vary depending on the ferroelectric material, the thickness of the ferroelectric material layer may also vary depending on the specific ferroelectric material used.

For example, the first and second gate insulating layers 121, 122 may each include a single ferroelectric material layer. In another example, the first and second gate insulating layers 121, 122 may each include a plurality of ferroelectric material layers spaced apart from each other. The first and second gate insulating layers 121, 122 may each have a stacked layer structure in which a plurality of ferroelectric material layers and a plurality of paraelectric material layers are alternately stacked.

The etching stop layer 160 may be disposed on the sidewall of each of the first and second gate spacers 111, 112 in the first horizontal direction DR1. The etching stop layer 160 may be disposed on the upper surface of the field insulating layer 105. The etching stop layer 160 may be disposed on the sidewall of each of the first to third source/drain regions SD1, SD2, SD3 in the second horizontal direction DR2. For example, the etching stop layer 160 may be disposed on both sidewalls of the third layer 143 of the first channel isolation layer 140 in the second horizontal direction DR2 on the upper surface of each of the first and second source/drain regions SD1, SD2. However, the present disclosure is not limited thereto. For example, the etching stop layer 160 may be formed conformally. The etching stop layer 160 may include at least one of aluminum oxide, aluminum nitride, hafnium oxide, zirconium oxide, silicon oxide, silicon nitride, silicon oxynitride, and a low-k dielectric material.

A first capping pattern 131 may extend in the second horizontal direction DR2 over the upper surface of each of the first gate spacer 111, the first gate insulating layer 121, the first gate electrode G1, and the etching stop layer 160. For example, a lower surface of the first capping pattern 131 may be in contact with the upper surface of the first layer 141 of the first channel isolation layer 140. The lower surface of the first capping pattern 131 may be in contact with the upper surface of the second layer 142 of the first channel isolation layer 140. A second capping pattern 132 may extend in the second horizontal direction DR2 over the upper surface of each of the second gate spacer 112, the second gate insulating layer 122, the second gate electrode G2, and the etching stop layer 160. For example, a lower surface of the second capping pattern 132 may be in contact with the upper surface of the second channel isolation layer 150. For example, each of the first and second capping patterns 131, 132 may include at least one of silicon nitride (SiN), silicon oxynitride (SiON), silicon oxide (SiO₂), silicon carbonitride (SiCN), silicon oxycarbonitride (SiOCN), or a combination thereof. However, the present disclosure is not limited thereto.

The interlayer insulating layer 170 may be disposed on the etching stop layer 160. The interlayer insulating layer 170 may cover each of the first to third source/drain regions SD1, SD2, SD3 on the field insulating layer 105. For example, the upper surface of the interlayer insulating layer 170 may be formed on the same plane as the upper surface of each of the first and second capping patterns 131, 132. For example, the upper surface of the interlayer insulating layer 170 may be formed on the same plane as the uppermost surface of each of the first and second channel isolation layers 140, 150. The interlayer insulating layer 170 may include at least one of silicon oxide, silicon nitride, silicon oxynitride, and a low-k dielectric material.

Each of the first to fifth source/drain contacts CA1 to CA5 may be disposed within the interlayer insulating layer 170. For example, the first source/drain contact CA1 and the second source/drain contact CA2 may be disposed on the upper surface of the first source/drain region SD1 disposed on both sidewalls of the first plurality of nanosheets NW1. For example, the second source/drain contact CA2 and the third source/drain contact CA3 may be disposed on the upper surface of the first source/drain region SD1 disposed on both sidewalls of the third plurality of nanosheets NW3. Each of the first to third source/drain contacts CA1, CA2, CA3 may be electrically connected to the first source/drain region SD1.

For example, the fourth source/drain contact CA4 may be disposed on the upper surface of the second source/drain region SD2 disposed on one side of the second plurality of nanosheets NW2. The fourth source/drain contact CA4 may be electrically connected to the second source/drain region SD2. For example, the fifth source/drain contact CA5 may be disposed on the upper surface of the third source/drain region SD3 disposed on one side of the fourth plurality of nanosheets NW4. The fifth source/drain contact CA5 may be electrically connected to the third source/drain region SD3. Each of the first to fifth source/drain contacts CA1 to CA5 may include a conductive material.

The silicide layer SL may be disposed along an interface between the first source/drain region SD1 and the first source/drain contact CA1. The silicide layer SL may be disposed along an interface between the first source/drain region SD1 and the second source/drain contact CA2. The silicide layer SL may be disposed along an interface between the first source/drain region SD1 and the third source/drain contact CA3. The silicide layer SL may be disposed along an interface between the second source/drain region SD2 and the fourth source/drain contact CA4. The silicide layer SL may be disposed along an interface between the third source/drain region SD3 and the fifth source/drain contact CA5. For example, the silicide layer SL may include a metal silicide material.

Each of the first gate contact CB1 and the second gate contact CB2 may penetrate (or extend into) the first capping pattern 131 in the vertical direction DR3 to be connected to the first gate electrode G1. For example, the first gate contact CB1 may be connected to the first gate electrode G1 disposed on a first sidewall of the first channel isolation layer 140. The second gate contact CB2 may be connected to the first gate electrode G1 disposed on a second sidewall of the first channel isolation layer 140 facing the first sidewall of the first channel isolation layer 140 in the second horizontal direction DR2. Each of the first gate contact CB1 and the second gate contact CB2 may include a conductive material.

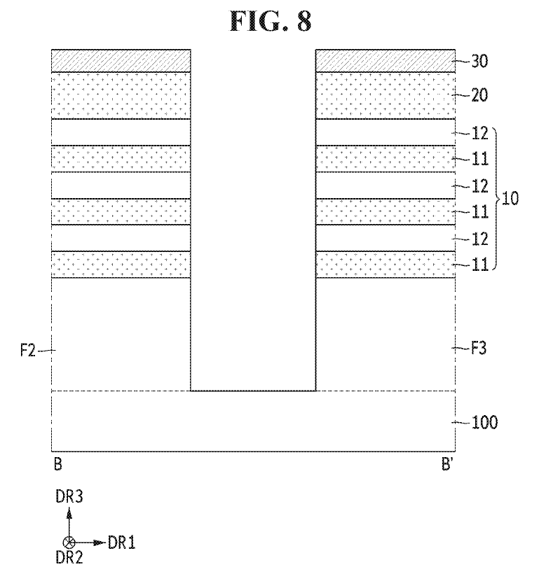

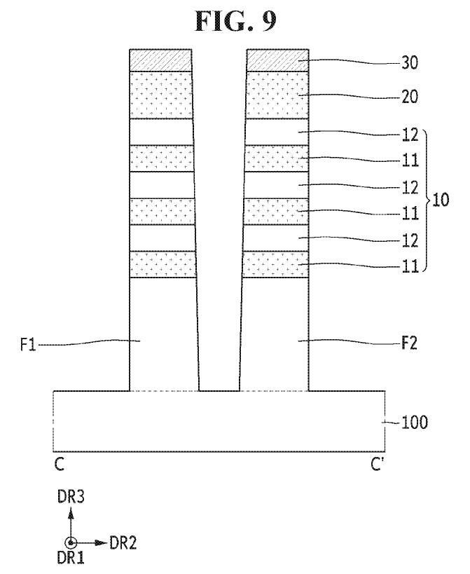

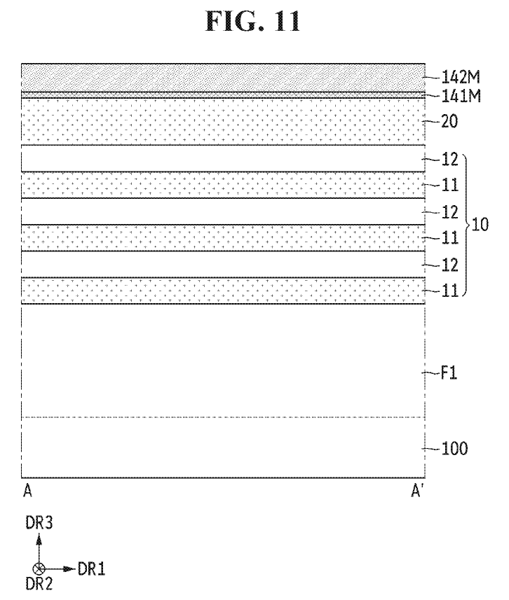

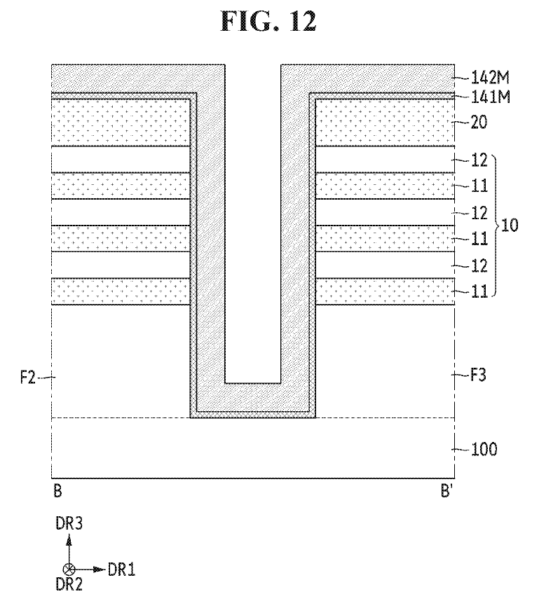

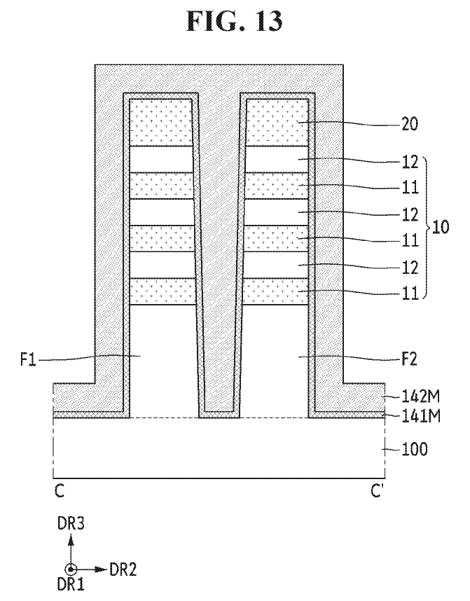

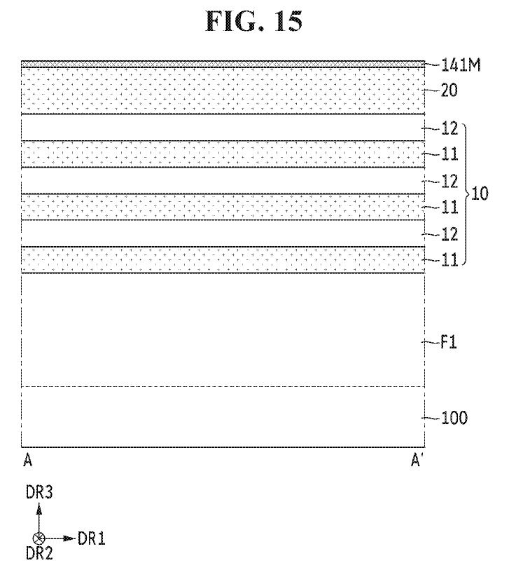

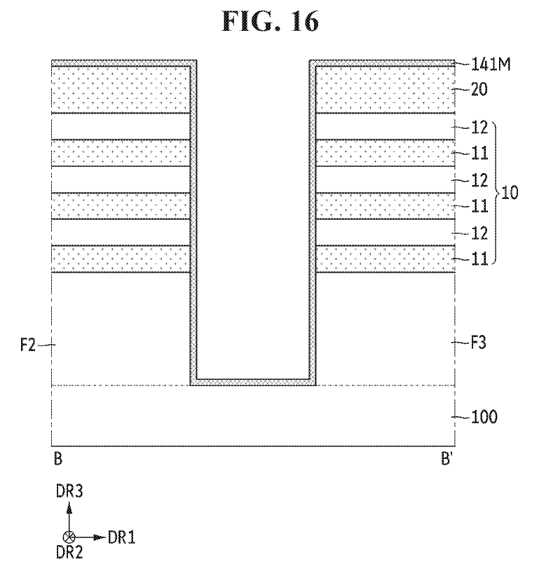

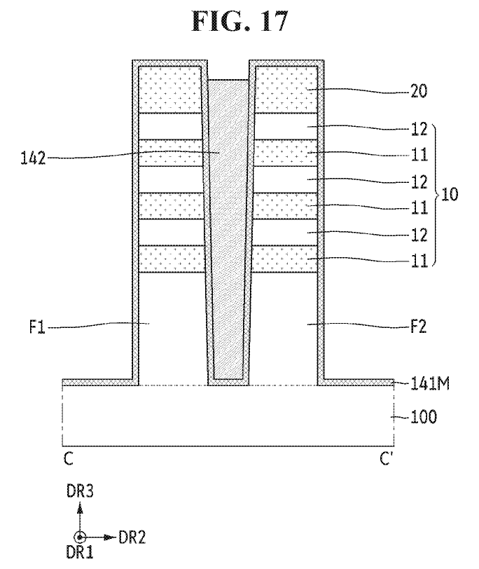

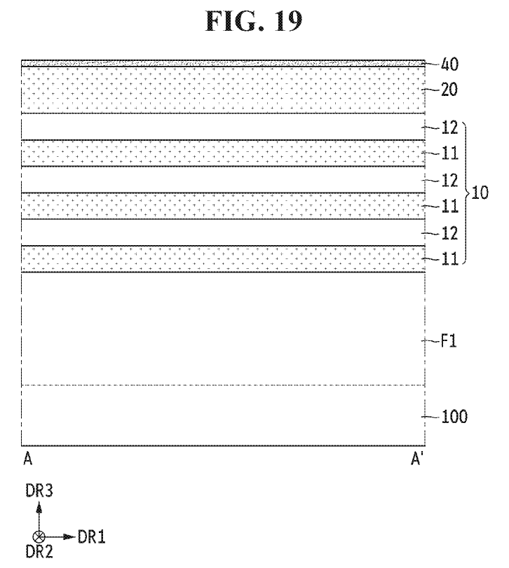

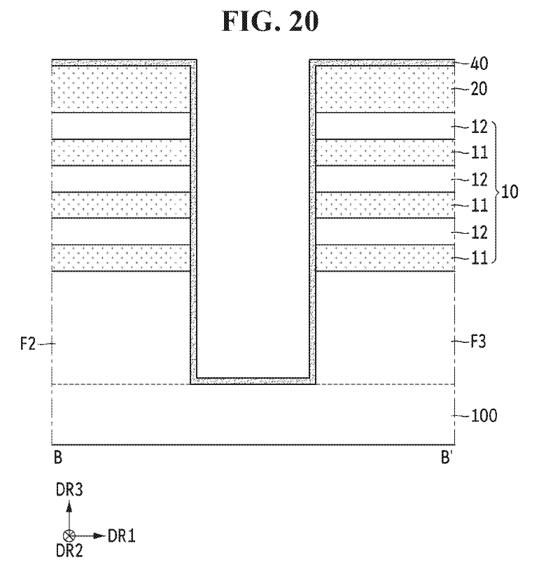

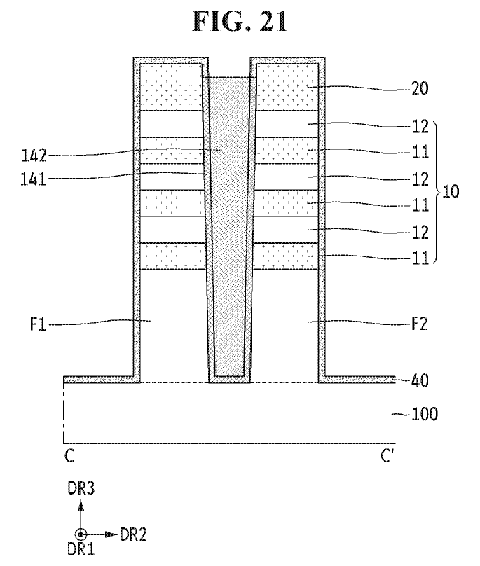

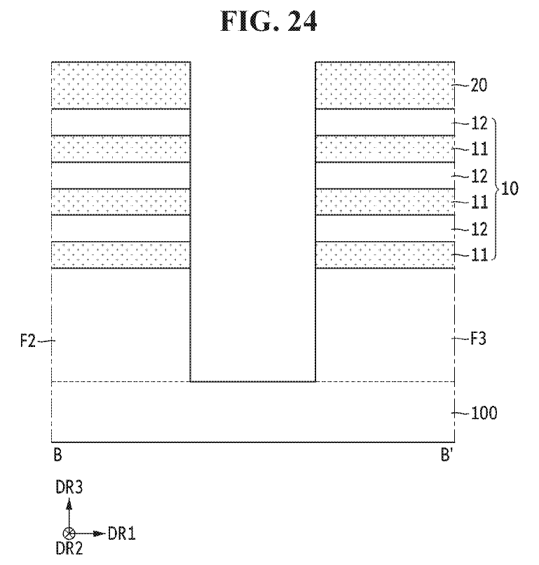

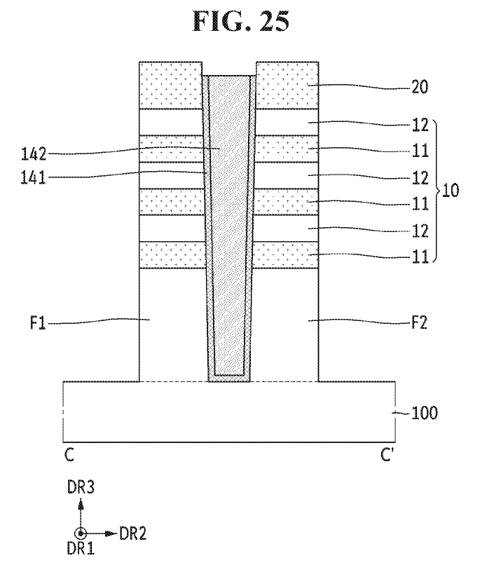

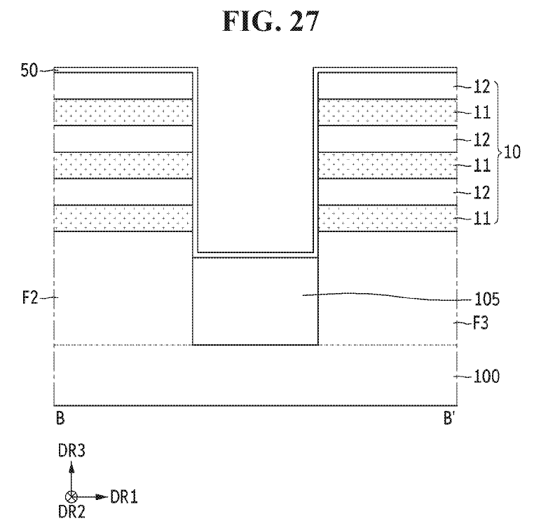

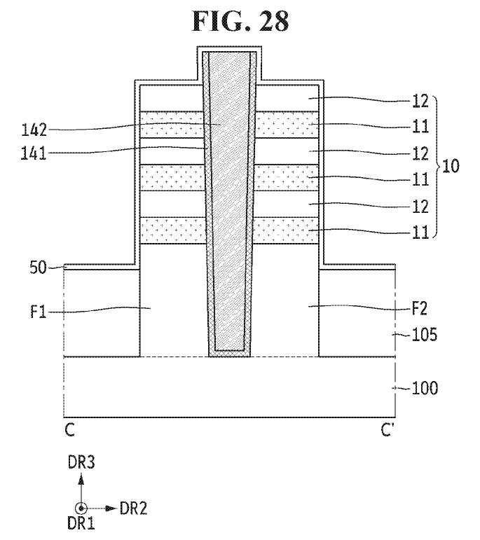

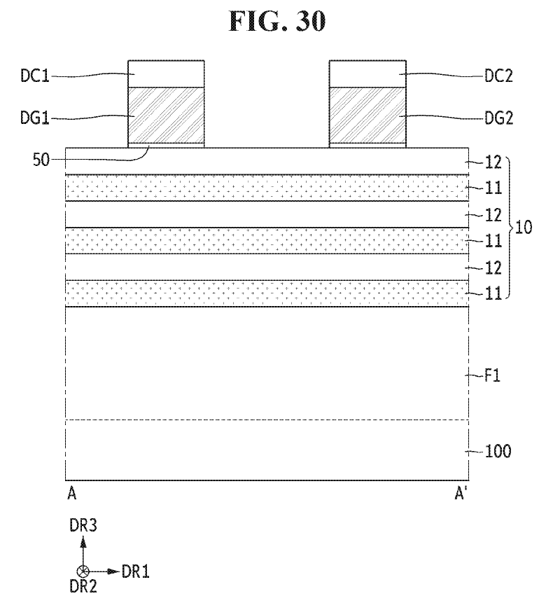

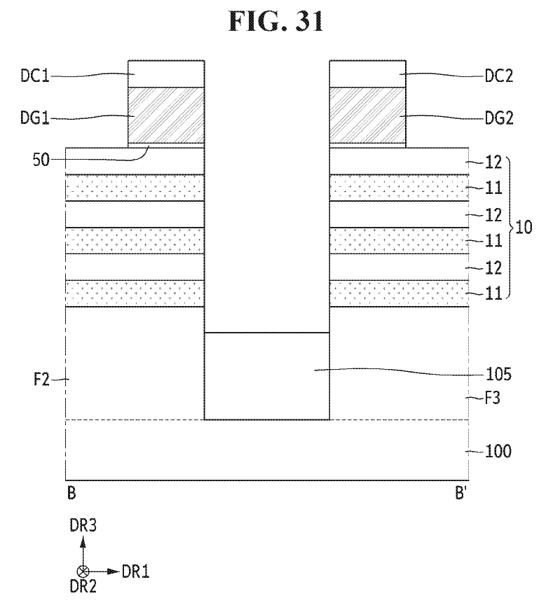

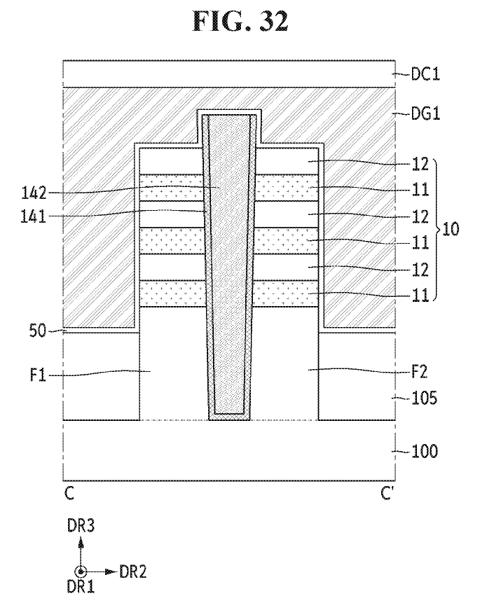

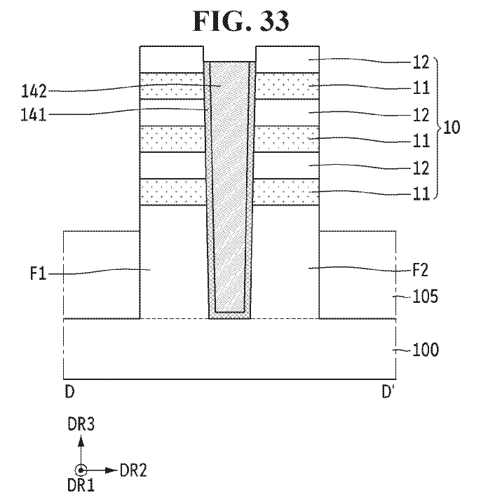

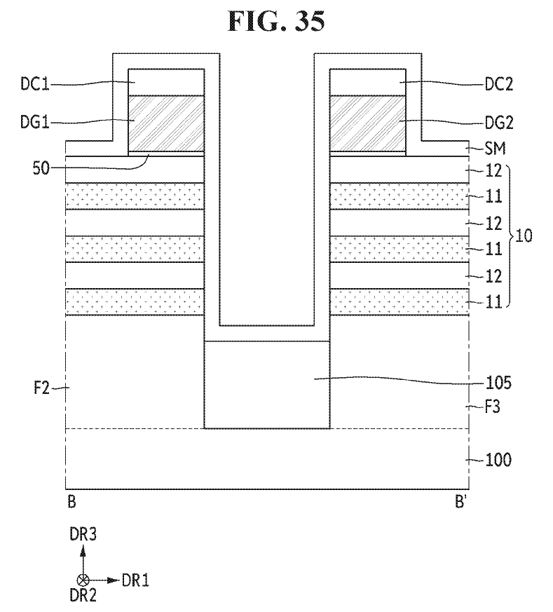

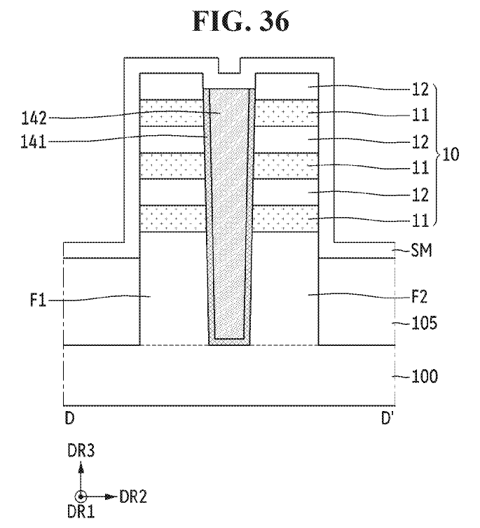

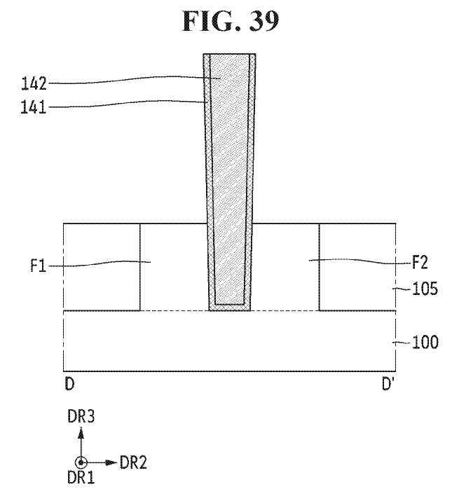

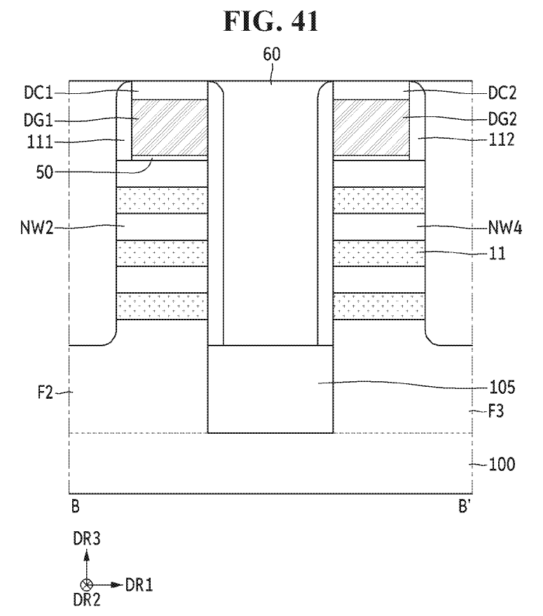

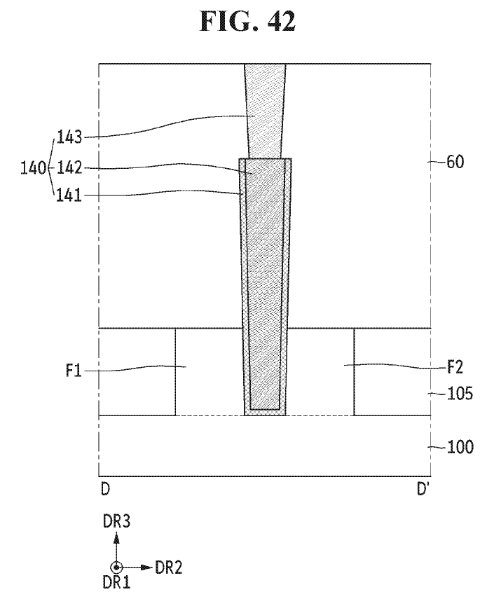

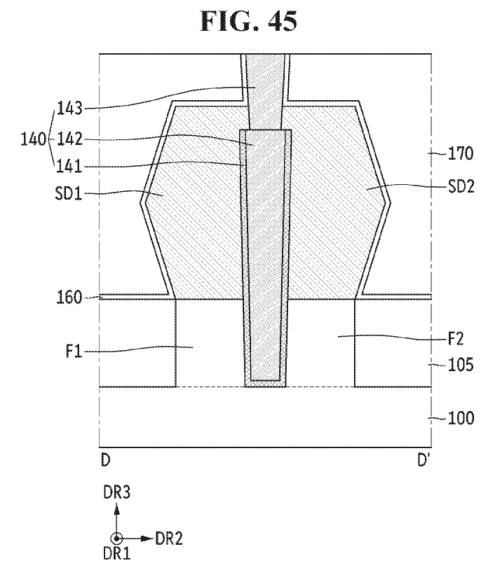

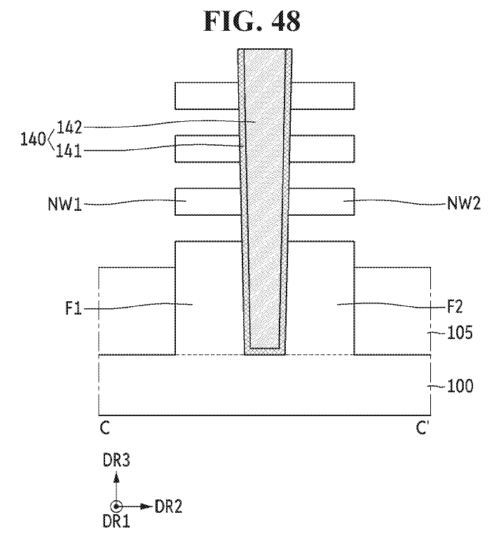

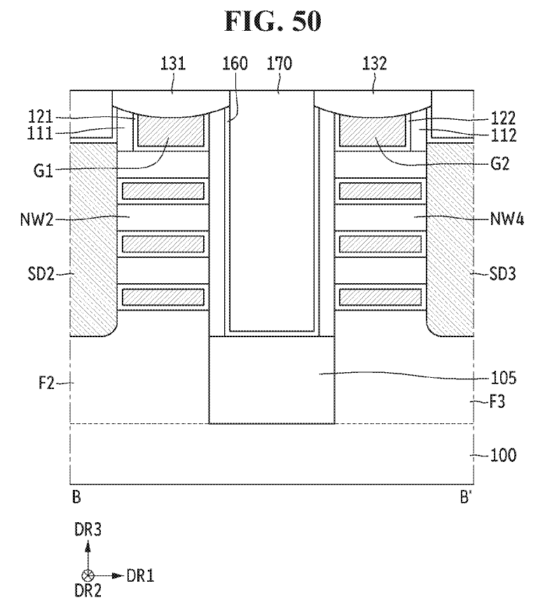

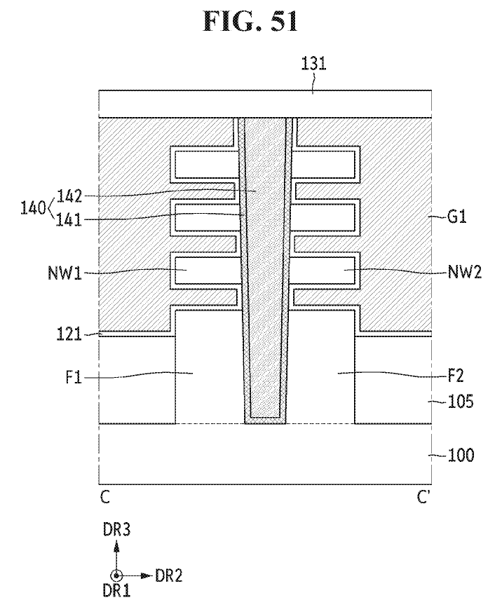

Hereinafter, a method for fabricating a semiconductor device according to several implementations of the present disclosure will be described with reference to FIGS. 1-51.

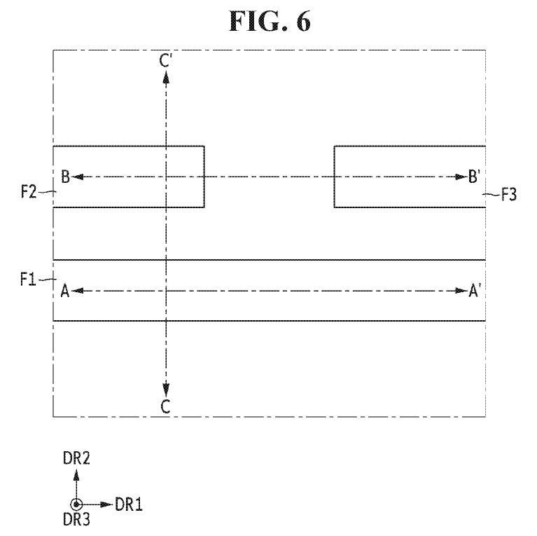

FIGS. 6-51 are intermediate stage diagrams for explaining the method for fabricating a semiconductor device according to some implementations of the present disclosure.

Referring to FIGS. 6-9, a stacked structure 10 may be formed on the upper surface of the substrate 100. The stacked structure 10 may include a first sacrificial layer 11 and a semiconductor layer 12 alternately stacked on the upper surface of the substrate 100. For example, the first sacrificial layer 11 may be formed at a lowermost portion of the stacked structure 10, and the semiconductor layer 12 may be formed at an uppermost portion of the stacked structure 10. For example, the first sacrificial layer 11 may include silicon germanium (SiGe), and the semiconductor layer 12 may include silicon (Si). Subsequently, a second sacrificial layer 20 may be formed on the upper surface of the stacked structure 10. For example, a thickness of the second sacrificial layer 20 in the vertical direction DR3 may be greater than a thickness of each of the first sacrificial layer 11 and the semiconductor layer 12 in the vertical direction DR3. For example, the second sacrificial layer 20 may include silicon germanium (SiGe).

Subsequently, a mask pattern 30 may be formed on an upper surface of the second sacrificial layer 20. The second sacrificial layer 20 and the stacked structure 10 may then be etched using the mask pattern 30 as a mask. While the second sacrificial layer 20 and the stacked structure 10 are being etched, a portion of the substrate 100 may also be etched. Through this etching process, first to third active patterns F1, F2, F3 may be formed under the stacked structure 10 on the upper surface of the substrate 100. For example, each of the first to third active patterns F1, F2, F3 may extend in the first horizontal direction DR1. Each of the second and third active patterns F2, F3 may be spaced apart from the first active pattern F1 in the second horizontal direction DR2. The third active pattern F3 may be spaced apart from the second active pattern F2 in the first horizontal direction DR1.

For example, portions of the stacked structure 10 and the second sacrificial layer 20 that do not overlap with each of the first to third active patterns F1, F2, F3 in the vertical direction DR3 may be etched. For example, the stacked structure 10 and the second sacrificial layer 20 formed on the upper surfaces of the second and third active patterns F2, F3 may be spaced apart from the stacked structure 10 and the second sacrificial layer 20 formed on the upper surface of the first active pattern F1 in the second horizontal direction DR2. Furthermore, the stacked structure 10 and the second sacrificial layer 20 formed on the upper surface of the third active pattern F3 may be spaced apart from the stacked structure 10 and the second sacrificial layer 20 formed on the upper surface of the second active pattern F2 in the first horizontal direction DR1.

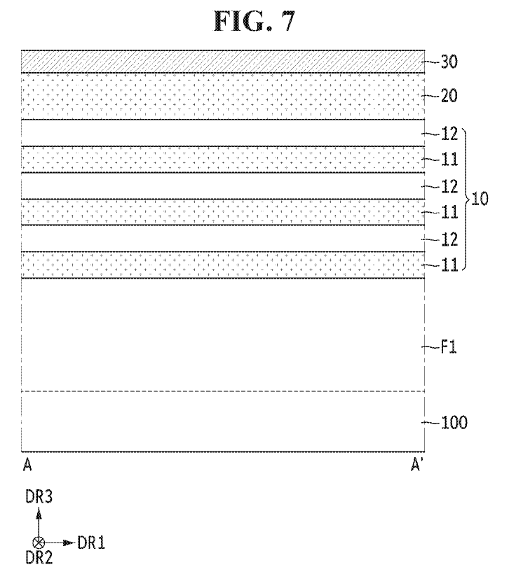

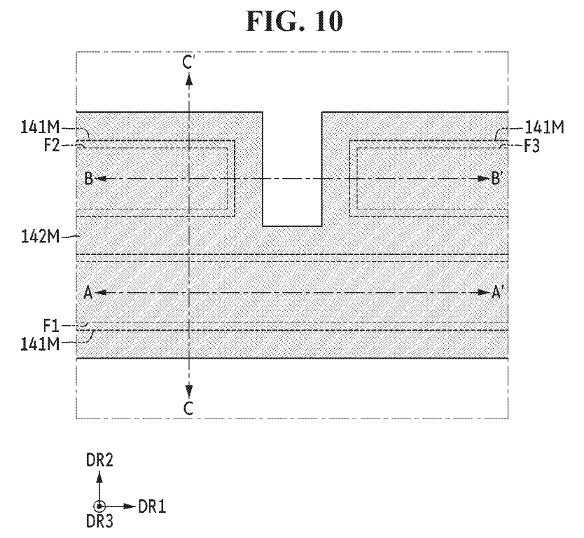

Referring to FIGS. 10-13, the mask pattern 30 (see FIGS. 7-9) may be removed. Subsequently, a first insulating material layer 141M may be formed on exposed surfaces of the substrate 100, the first to third active patterns F1, F2, F3, the stacked structure 10, and the second sacrificial layer 20. For example, the first insulating material layer 141M may be conformally formed. The first insulating material layer 141M may include silicon oxycarbide (SiOC). In some other implementations, the first insulating material layer 141M may include any one of silicon carbonitride (SiCN) or silicon oxycarbonitride (SiOCN).

Thereafter, a second insulating material layer 142M may be formed on the first insulating material layer 141M. For example, the second insulating material layer 142M may be conformally formed. A thickness of the second insulating material layer 142M may be greater than a thickness of the first insulating material layer 141M. For example, the first insulating material layer 141M and the second insulating material layer 142M may completely fill the space between the first active pattern F1 and the second active pattern F2. The first insulating material layer 141M and the second insulating material layer 142M may also completely fill the space between the first active pattern F1 and the third active pattern F3. The second insulating material layer 142M may include a different material from the first insulating material layer 141M. For example, the second insulating material layer 142M may include silicon nitride (SiN).

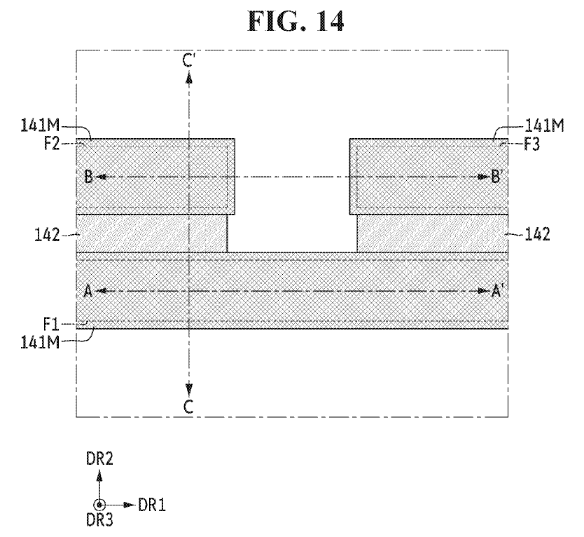

Referring to FIGS. 14-17, a portion of the second insulating material layer 142M (see FIGS. 10-13) may be etched. For example, the remaining portions of the second insulating material layer 142M (see FIGS. 10-13), except for the portions of the second insulating material layer 142M (see FIGS. 10-13) formed between the stacked structure 10 on the first active pattern F1 and the stacked structure 10 on the second active pattern F2, and between the stacked structure 10 on the first active pattern F1 and the stacked structure 10 on the third active pattern F3, may be etched. For example, the remaining portion of the second insulating material layer 142M (see FIGS. 10-13) may be defined as the second layer 142. For example, the upper surface of the second layer 142 may be formed higher, in relation to the substrate, than the upper surface of the stacked structure 10. For example, the upper surface of the second layer 142 may be formed lower than the upper surface of the second sacrificial layer 20.

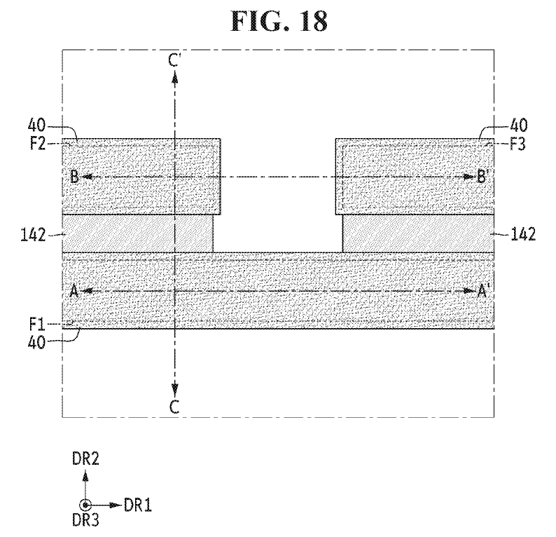

Referring to FIGS. 18-21, the exposed first insulating material layer 141M (see FIGS. 14-17) may be oxidized to form a third insulating material layer 40. For example, the third insulating material layer 40 may include silicon oxide (SiO₂). For example, the remaining portion of the first insulating material layer 141M (see FIGS. 14-17) that is not oxidized may be defined as the first layer 141. For example, the upper surface of the first layer 141 and the upper surface of the second layer 142 may be formed on the same plane. However, the present disclosure is not limited thereto.

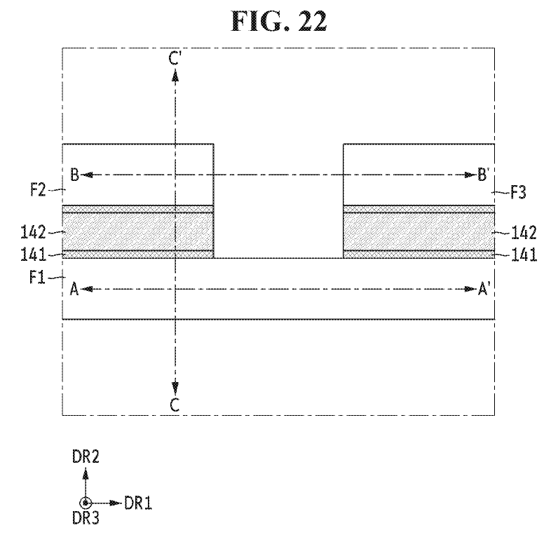

Referring to FIGS. 22-25, the third insulating material layer 40 (see FIGS. 18-21) may be etched.

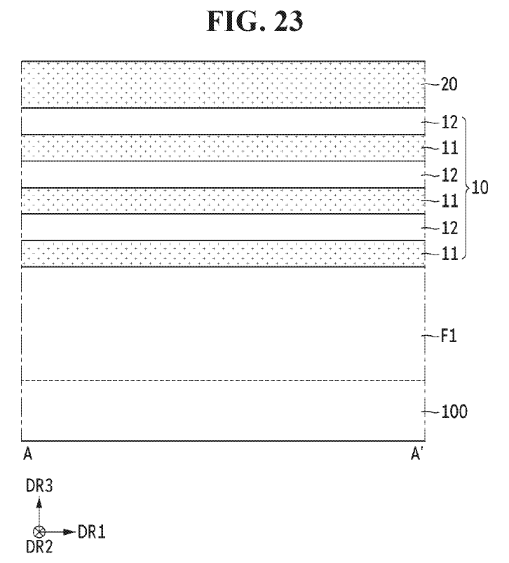

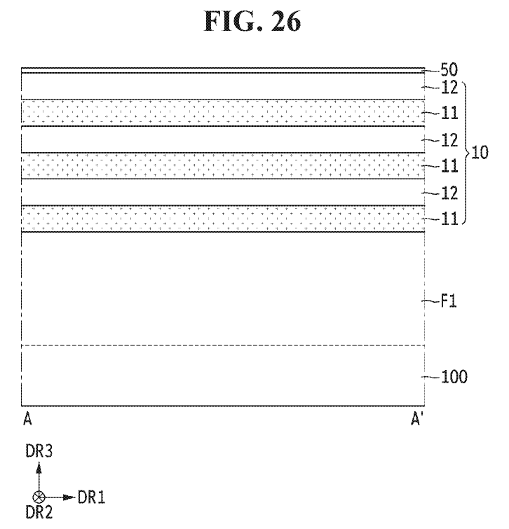

Referring to FIGS. 26-28, the second sacrificial layer 20 (see FIGS. 23-25) may be etched. Subsequently, the field insulating layer 105 surrounding the sidewalls of the first, second, and third active patterns F1, F2, F3 on an upper surface of the substrate 100 may be formed. For example, the lowermost surface of the first layer 141 may be formed lower than the upper surface of the field insulating layer 105. Subsequently, a pad oxide layer 50 may be formed on exposed surfaces of the field insulating layer 105, the first to third active patterns F1, F2, F3, the stacked structure 10, the first layer 141, and the second layer 142. For example, the pad oxide layer 50 may be conformally formed. For example, the pad oxide layer 50 may include silicon oxide (SiO₂).

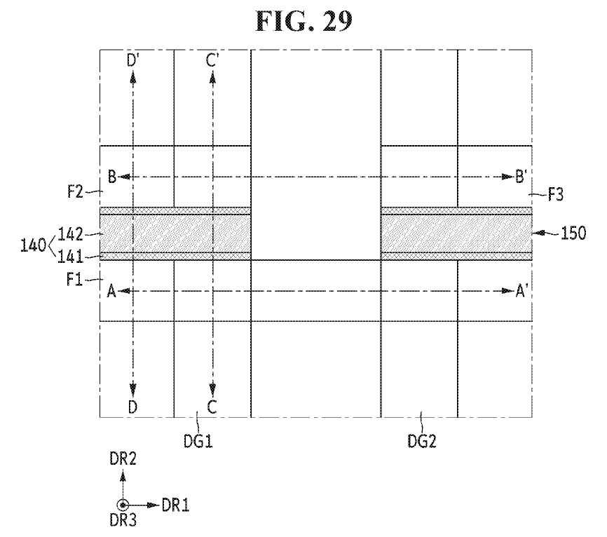

Referring to FIGS. 29-33, a first dummy gate DG1 and a second dummy gate DG2, and a first dummy capping pattern DC1 and a second dummy capping pattern DC2, each extending in the second horizontal direction DR2, may be formed on the pad oxide layer 50. The first dummy capping pattern DC1 may be formed on the first dummy gate DG1. Additionally, the second dummy capping pattern DC2 may be formed on the second dummy gate DG2. The second dummy gate DG2 and the second dummy capping pattern DC2 may be spaced apart from the first dummy gate DG1 and the first dummy capping pattern DC1, respectively, in the first horizontal direction DR1.

Subsequently, the remaining portions of the pad oxide layer 50, except for the portions overlapping with each of the first and second dummy gates DG1, DG2 in the vertical direction DR3, may be etched. During the etching of the pad oxide layer 50, portions of each of the first layer 141 and the second layer 142 in regions where the first and second dummy gates DG1, DG2 are not formed may also be etched. For example, in regions where the first and second dummy gates DG1 and DG2 are not formed, the upper surfaces of the remaining first layer 141 and second layer 142 may be formed lower than the upper surface of the stacked structure 10.

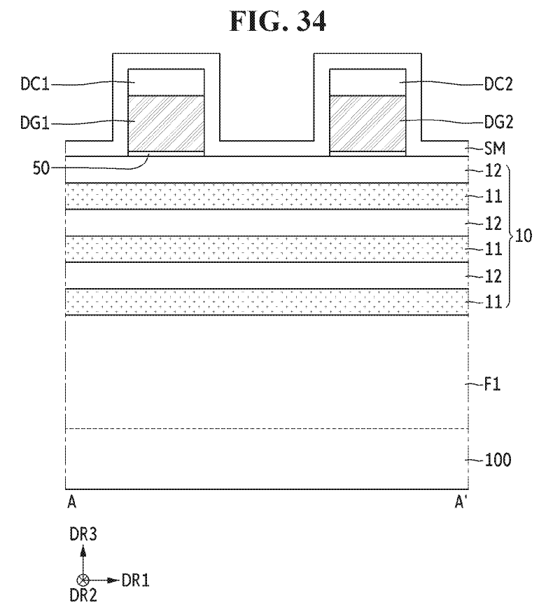

Referring to FIGS. 34-36, a spacer material layer SM may be formed on the exposed surface of each of the field insulating layer 105, the first to third active patterns F1, F2, F3, the stacked structure 10, the pad oxide layer 50, the first and second dummy gates DG1, DG2, the first and second dummy capping patterns DC1, DC2, and the first and second layers 141, 142. For example, the spacer material layer SM may be conformally formed. The spacer material layer SM may include one or more of silicon nitride (SiN), silicon oxynitride (SiON), silicon oxide (SiO₂), silicon carbonitride (SiCN), silicon oxycarbonitride (SiOCN), silicon boronitride (SiBN), silicon oxyboronitride (SiOBN), silicon boron carbide (SiBC), silicon boron carbonitride (SiBCN), silicon oxycarbide (SiOC), and combinations thereof. However, the present disclosure is not limited thereto.

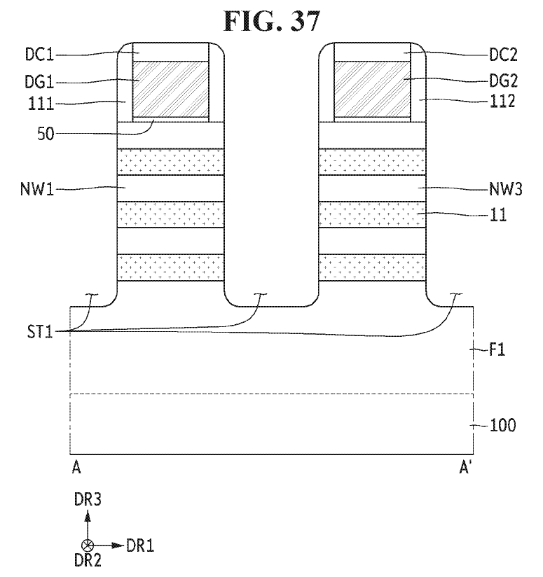

Referring to FIGS. 37-39, the stacked structure 10 (see FIGS. 34-36) may be etched using the first and second dummy capping patterns DC1, DC2 and the first and second dummy gates DG1, DG2 as masks, to form first to third source/drain trenches ST1, ST2, ST3. For example, the first source/drain trench ST1 may be formed on both sides of the first and second dummy gates DG1, DG2 over the first active pattern F1. The second source/drain trench ST2 may be formed on one side of the first dummy gate DG1 over the second active pattern F2. The third source/drain trench ST3 may be formed on one side of the second dummy gate DG2 over the third active pattern F3.

For example, in regions where the first to third source/drain trenches ST1, ST2, ST3 are formed, both sidewalls of the first layer 141 in the second horizontal direction DR2 may be exposed on the upper surfaces of the first to third active patterns F1, F2, F3, respectively. After the first to third source/drain trenches ST1, ST2, ST3 are formed, the spacer material layer SM remaining on both sidewalls of the first dummy gate DG1 may be defined as the first gate spacer 111, and the spacer material layer SM remaining on both sidewalls of the second dummy gate DG2 may be defined as the second gate spacer 112.

For example, after the first to third source/drain trenches ST1, ST2, ST3 are formed, the semiconductor layer 12 (see FIGS. 34-36) remaining under the first dummy gate DG1 on the first active pattern F1 may be defined as the first plurality of nanosheets NW1. The semiconductor layer 12 (see FIGS. 34-36) remaining under the first dummy gate DG1 on the second active pattern F2 may be defined as the second plurality of nanosheets NW2. The semiconductor layer 12 (see FIGS. 34-36) remaining under the second dummy gate DG2 on the first active pattern F1 may be defined as the third plurality of nanosheets NW3. The semiconductor layer 12 (see FIGS. 34-36) remaining under the second dummy gate DG2 on the third active pattern F3 may be defined as the fourth plurality of nanosheets NW4.

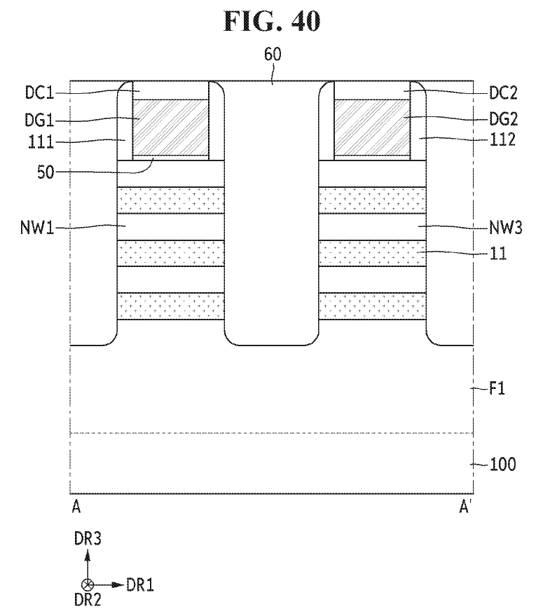

Referring to FIGS. 40-42, a protective layer 60 may be formed to fill each of the first to third source/drain trenches ST1, ST2, ST3. For example, the protective layer 60 may surround the sidewall of each of the first and second gate spacers 111, 112. The protective layer 60 may also cover the upper surfaces of the first and second layers 141 and 142 in regions where the first and second dummy gates DG1, DG2 are not formed. The protective layer 60 may include a SOH (spin-on hardmask). Subsequently, the third layer 143 may be formed by penetrating the protective layer 60 in the vertical direction DR3 and connecting to the second layer 142. As a result, the first channel isolation layer 140 including the first layer 141, the second layer 142, and the third layer 143 may be formed.

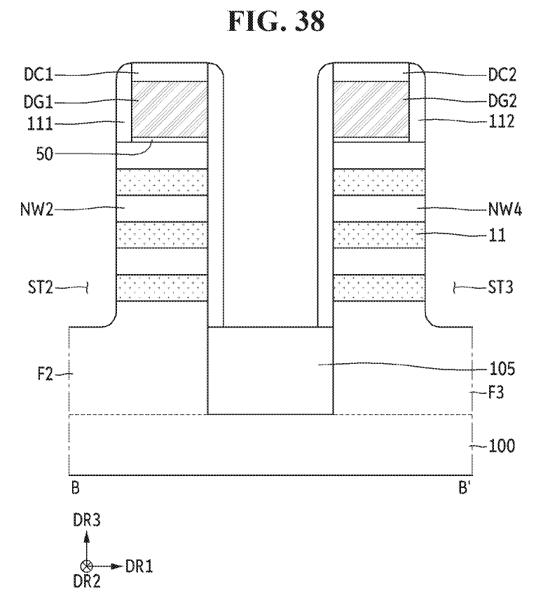

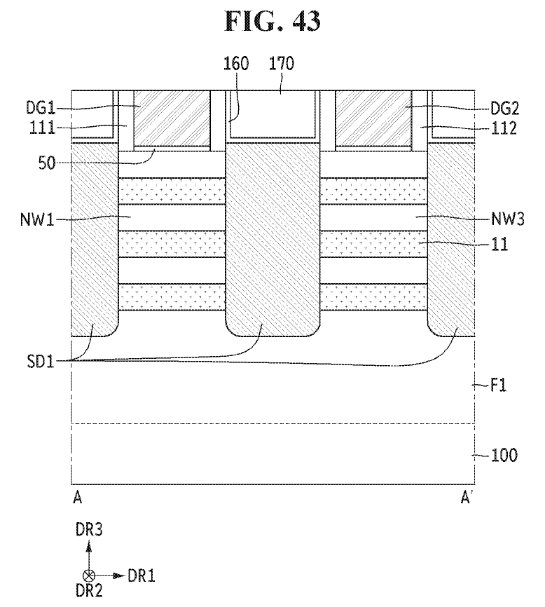

Referring to FIGS. 43-45, the protective layer 60 (see FIGS. 40-42) may be removed. Subsequently, the first source/drain region SD1 may be formed within the first source/drain trench ST1 (see FIG. 37), the second source/drain region SD2 may be formed within the second source/drain trench ST2 (see FIG. 38), and the third source/drain region SD3 may be formed within the third source/drain trench ST3 (see FIG. 38). Subsequently, after the etching stop layer 160 and the interlayer insulating layer 170 are sequentially formed, a planarization process may be performed to expose the upper surfaces of the first and second dummy gates DG1, DG2.

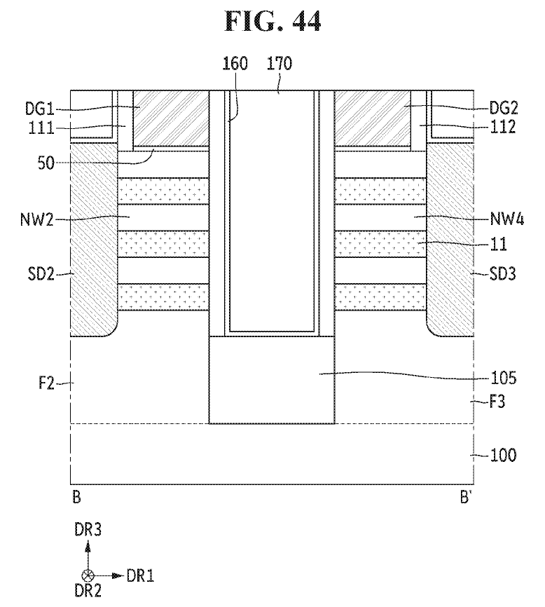

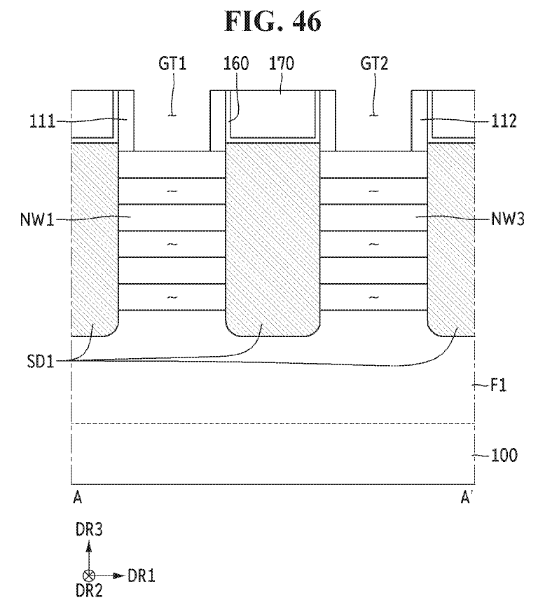

Referring to FIGS. 46-48, the first and second dummy gates DG1, DG2 (see FIGS. 43 and 44), the pad oxide layer 50 (see FIGS. 43 and 44), and the first sacrificial layer 11 (see FIGS. 43 and 44) may be etched. For example, the region in which the first dummy gate DG1 (see FIGS. 43 and 44), the pad oxide layer 50 (see FIGS. 43 and 44), and the first sacrificial layer 11 (see FIGS. 43 and 44) are etched may be defined as a first gate trench GT1. Similarly, the region in which the second dummy gate DG2 (see FIGS. 43 and 44), the pad oxide layer 50 (see FIGS. 43 and 44), and the first sacrificial layer 11 (see FIGS. 43 and 44) are etched may be defined as a second gate trench GT2.

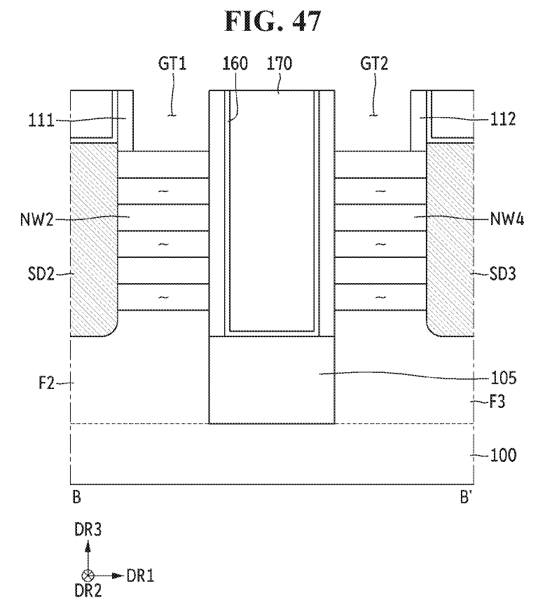

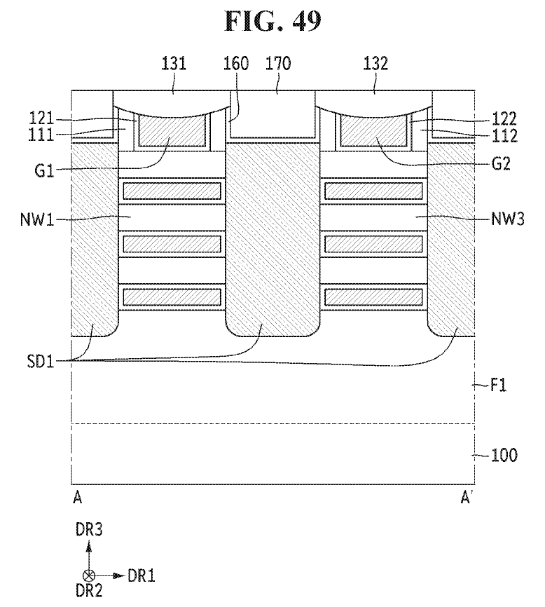

Referring to FIGS. 49-51, the first gate insulating layer 121, the first gate electrode G1, and the first capping pattern 131 may be sequentially formed within the first gate trench GT1 (see FIGS. 46 and 47). In addition, the second gate insulating layer 122, the second gate electrode G2, and the second capping pattern 132 may be sequentially formed within the second gate trench GT2 (see FIGS. 46 and 47). For example, the first gate electrode G1 may surround each of the first plurality of nanosheets NW1 and the second plurality of nanosheets NW2. The second gate electrode G2 may surround each of the third plurality of nanosheets NW3 and the fourth plurality of nanosheets NW4.

Referring to FIGS. 1-5, each of the first to fifth source/drain contacts CA1 to CA5 may be disposed within the interlayer insulating layer 170. For example, the first to the third source/drain contacts CA1 to CA3 may be formed on the upper surface of the first source/drain region SD1, the fourth source/drain contact CA4 may be formed on the upper surface of the second source/drain region SD2, and the fifth source/drain contact CA5 may be formed on the upper surface of the third source/drain region SD3. In addition, the silicide layer SL may be formed along the interface between each of the first to fifth source/drain contacts CA1 to CA5 and each of the first to third source/drain regions SD1 to SD3. Furthermore, the first gate contact CB1 and the second gate contact , which penetrate (or extend into) the first capping pattern 131 in the vertical direction DR3 and are connected to the first gate electrode G1, may be formed. Through such a fabrication process, the semiconductor device as shown in FIGS. 1-5 may be fabricated.

For example, when the channel isolation layer that separates the first active pattern F1 and the second active pattern F2 in the second horizontal direction DR2 is formed as a single layer, defects may occur due to excessive etching of the channel isolation layer in the first horizontal direction DR1 during the process of forming the channel isolation layer. According to some implementations of the present disclosure, a method for fabricating a semiconductor device may include forming a multilayer structure comprising a first layer 141 and a second layer 142, the multilayer structure separating the stacked structure 10, the first active pattern F1, and the second active pattern F2 in the second horizontal direction DR2. Therefore, during the process of forming the first layer 141 and the second layer 142, excessive etching of the first layer 141 and the second layer 142 may be prevented, thereby improving the reliability of the semiconductor device.

In the semiconductor device according to some implementations of the present disclosure, the first channel isolation layer 140 separating the first and the second active patterns F1, F2 and the first and the second plurality of nanosheets NW1, NW2 from each other in the second horizontal direction DR2 may include the first layer 141 and the second layer 142. The first layer 141 and the second layer 142 may include different materials. The lower surface of the first channel isolation layer 140 may be formed lower than the upper surface of the field insulating layer 105. The first layer 141 may be in contact with the sidewall of each of the first and the second plurality of nanosheets NW1, NW2 in the second horizontal direction DR2. The first gate insulating layer 121 may not be disposed (or absent) between the first layer 141 and the sidewall of the lowermost nanosheets of each of the first and the second plurality of nanosheets NW1, NW2 in the second horizontal direction DR2.

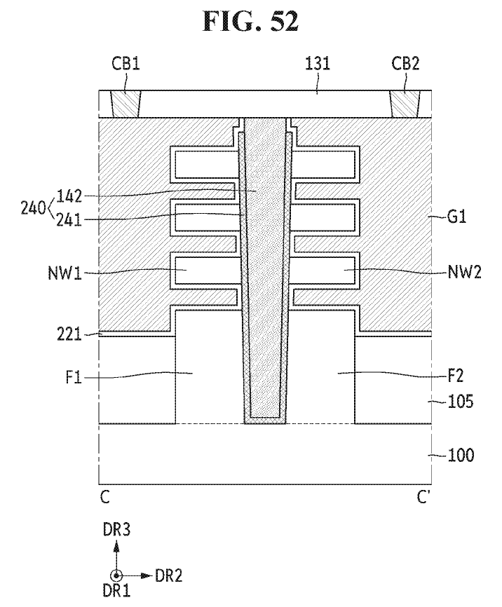

Referring to FIG. 52, the semiconductor device according to some implementations of the present disclosure will be described, focusing on differences from the semiconductor device shown in FIGS. 1-5.

FIG. 52 is a cross-sectional view for explaining a semiconductor device according to other implementations of the present disclosure.

Referring to FIG. 52, in the semiconductor device according to some implementations of the present disclosure, an uppermost surface of the second layer 142 of the first channel isolation layer 240 may be higher, in relation to the substrate, than an uppermost surface of the first layer 241 of the first channel isolation layer 240.

For example, the uppermost surface of the second layer 142 of the first channel isolation layer 240 may be in contact with the lower surface of the first capping pattern 131. The lower surface of the first capping pattern 131 may be spaced apart from the uppermost surface of the first layer 241 of the first channel isolation layer 240 in the vertical direction DR3. The uppermost surface of the first layer 241 of the first channel isolation layer 240 may be formed higher, in relation to the substrate, than the upper surface of the uppermost nanosheets of each of the first and the second plurality of nanosheets NW1, NW2. For example, at least a portion of the first gate insulating layer 221 may be in contact with the second layer 142 of the first channel isolation layer 240. On the uppermost surface of the first layer 241 of the first channel isolation layer 240, the first gate insulating layer 221 may be in contact with the sidewall of the second layer 142 of the first channel isolation layer 240 in the second horizontal direction DR2.

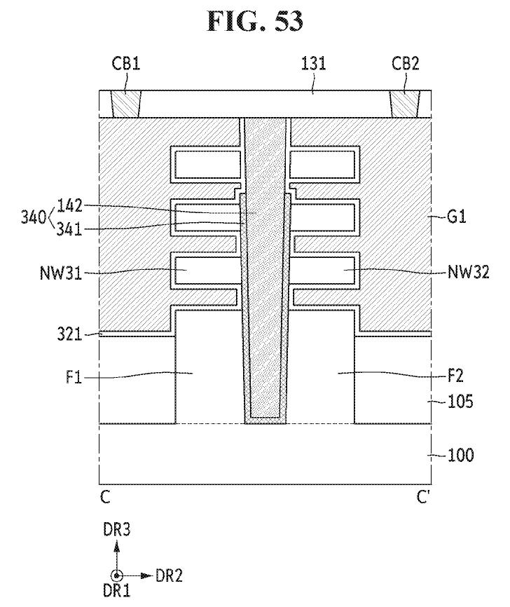

Referring to FIG. 53, the semiconductor device according to some implementations of the present disclosure will be described, focusing on differences from the semiconductor device shown in FIGS. 1-5.

FIG. 53 is a cross-sectional view for explaining a semiconductor device according to several other implementations of the present disclosure.

Referring to FIG. 53, in the semiconductor device according to some implementations of the present disclosure, the first gate insulating layer 321 may be disposed between the uppermost nanosheets of the first and the second plurality of nanosheets NW31, NW32 and the second layer 142 of the first channel isolation layer 340.

For example, the sidewalls of the lowermost nanosheets of the first and the second plurality of nanosheets NW31, NW32 in the second horizontal direction DR2 may be in contact with the first layer 341 of the first channel isolation layer 340. That is, the first gate insulating layer 321 may not be disposed (or absent) between the lowermost nanosheets of the first and the second plurality of nanosheets NW31, NW32 and the first layer 341 of the first channel isolation layer 340. The uppermost surface of the first layer 341 of the first channel isolation layer 340 may be formed higher, in relation to the substrate, than upper surfaces of the lowermost nanosheets of the first and the second plurality of nanosheets NW31, NW32. In addition, the uppermost surface of the first layer 341 of the first channel isolation layer 340 may be formed lower than lower surfaces of the uppermost nanosheets of the first and the second plurality of nanosheets NW31, NW32. For example, at least a portion of the first gate insulating layer 321 may be in contact with the second layer 142 of the first channel isolation layer 340. On the uppermost surface of the first layer 341 of the first channel isolation layer 340, the first gate insulating layer 321 may be in contact with the sidewall of the second layer 142 of the first channel isolation layer 340 in the second horizontal direction DR2.

According to some implementations of the present disclosure, there is provided a method for fabricating a semiconductor device, comprising forming a stacked structure in which first sacrificial layers including silicon germanium (SiGe) and semiconductor layers including silicon (Si) are alternately stacked on an upper surface of a substrate, forming a first active pattern and a second active pattern, each extending in a first horizontal direction under the stacked structure, by etching the stacked structure and a portion of the substrate, wherein the second active pattern is spaced apart from the first active pattern in a second horizontal direction different from the first horizontal direction, forming a first insulating material layer on exposed surfaces of the substrate, the first and second active patterns, and the stacked structure, forming a second insulating material layer including a material different from a material of the first insulating material layer on the first insulating material layer, etching the second insulating material layer except for a portion formed between the stacked structure on the first active pattern and the stacked structure on the second active pattern, and defining a remaining portion of the second insulating material layer as a second layer, forming a third insulating material layer by oxidizing a portion of the exposed first insulating material layer, and defining a remaining unoxidized portion of the first insulating material layer as a first layer, etching the third insulating material layer, etching the stacked structure, wherein a portion of the semiconductor layers remaining on the first active pattern is defined as a first plurality of nanosheets, and a portion of the semiconductor layers remaining on the second active pattern is defined as a second plurality of nanosheets, and forming a gate electrode extending in the second horizontal direction on the first and second active patterns, the gate electrode surrounding the first and second plurality of nanosheets, wherein the first layer is in contact with the upper surface of the substrate, a sidewall of each of the first and second active patterns, and a sidewall of each of the first and second plurality of nanosheets, and wherein the second layer is surrounded by the first layer.

According to some implementations of the present disclosure, there is provided a method for fabricating a semiconductor device, comprising after etching the third insulating material layer, forming a field insulating layer surrounding the sidewall of each of the first and second active patterns on the upper surface of the substrate, wherein a lowermost surface of the first layer is formed lower than an upper surface of the field insulating layer.

According to some implementations of the present disclosure, there is provided a method for fabricating a semiconductor device, comprising wherein each of the first and second plurality of nanosheets is in contact with the first layer.

According to some implementations of the present disclosure, there is provided a method for fabricating a semiconductor device, comprising after forming each of the first and second plurality of nanosheets, etching the sacrificial layers, and forming the gate electrode surrounding the first and second plurality of nanosheets on the first and second active patterns, wherein the gate electrode is separated in the second horizontal direction by the second layer.

According to some implementations of the present disclosure, there is provided a method for fabricating a semiconductor device, comprising before forming the gate electrode, forming a gate insulating layer between the gate electrode and the first plurality of nanosheets and between the gate electrode and the first layer, wherein the gate insulating layer is not formed between a lowermost nanosheet of the first plurality of nanosheets and the first layer.

While the implementations of the present disclosure have been described above with reference to the accompanying drawings, it will be understood that the present disclosure is not limited to these implementations and may be implemented in various other forms. Those skilled in the art will recognize that the disclosure can be practiced in other specific without departing from its technical concept or essential features. Accordingly, the above-described implementations should be considered illustrative in all respects and not restrictive.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate;
a first active pattern extending in a first horizontal direction on the substrate;
a second active pattern extending in the first horizontal direction on the substrate, wherein the second active pattern is spaced apart from the first active pattern in a second horizontal direction different from the first horizontal direction;
a field insulating layer surrounding each of the first active pattern and the second active pattern on the substrate;
a first plurality of nanosheets spaced apart from each other in a vertical direction on an upper surface of the first active pattern;
a second plurality of nanosheets spaced apart from each other in the vertical direction on an upper surface of the second active pattern, wherein the second plurality of nanosheets are spaced apart from the first plurality of nanosheets in the second horizontal direction; and
a first channel isolation layer extending in the first horizontal direction between the first active pattern and the second active pattern, wherein the first channel isolation layer is in contact with a sidewall of each of the first plurality of nanosheets and the second plurality of nanosheets, wherein a lower surface of the first channel isolation layer is lower than an upper surface of the field insulating layer,
wherein the first channel isolation layer comprises
a first layer in contact with a sidewall of the first active pattern and the second active pattern and in contact with the sidewall of each of the first plurality of nanosheets and the second plurality of nanosheets, wherein the first layer defines a lower surface and sidewalls of the first channel isolation layer, and
a second layer surrounded by the first layer, wherein a material of the second layer is different from a material of the first layer.

2. The semiconductor device of claim 1, comprising:
a gate electrode extending in the second horizontal direction on an upper surface of each of the field insulating layer, the first active pattern, and the second active pattern, wherein the gate electrode surrounds the first plurality of nanosheets and the second plurality of nanosheets.

3. The semiconductor device of claim 2, comprising:
a gate insulating layer between the gate electrode and the first plurality of nanosheets and between the gate electrode and the first channel isolation layer, wherein a sidewall of a lowermost nanosheet of the first plurality of nanosheets is in contact with the first channel isolation layer.

4. The semiconductor device of claim 3, wherein at least a portion of the gate insulating layer is in contact with the second layer.

5. The semiconductor device of claim 1, wherein a width of the second plurality of nanosheets in the first horizontal direction is smaller than a width of the first plurality of nanosheets in the first horizontal direction.

6. The semiconductor device of claim 1, wherein an uppermost surface of the second layer is higher, in relation to the substrate, than an upper surface of an uppermost nanosheet of the first plurality of nanosheets.

7. The semiconductor device of claim 1, wherein the lower surface of the first channel isolation layer is in contact with an upper surface of the substrate.

8. The semiconductor device of claim 1, comprising:
a third active pattern extending in the first horizontal direction on the substrate, wherein the third active pattern is spaced apart from the first active pattern in the second horizontal direction, and wherein the third active pattern is spaced apart from the second active pattern in the first horizontal direction; and
a second channel isolation layer extending in the first horizontal direction between the first active pattern and the third active pattern, wherein the second channel isolation layer is spaced apart from the first channel isolation layer in the first horizontal direction.

9. The semiconductor device of claim 1, wherein an uppermost surface of the first layer is formed higher, in relation to the substrate, than an upper surface of an uppermost nanosheet of the first plurality of nanosheets.

10. The semiconductor device of claim 1, wherein an uppermost surface of the second layer is higher, in relation to the substrate, than an uppermost surface of the first layer.

11. The semiconductor device of claim 1, wherein an uppermost surface of the second layer is formed on a same plane as an uppermost surface of the first layer.

12. A semiconductor device comprising:
a substrate;
a first active pattern extending in a first horizontal direction on the substrate;
a second active pattern extending in the first horizontal direction on the substrate, wherein the second active pattern is spaced apart from the first active pattern in a second horizontal direction different from the first horizontal direction;
a first plurality of nanosheets spaced apart from each other in a vertical direction on an upper surface of the first active pattern;
a second plurality of nanosheets spaced apart from each other in the vertical direction on an upper surface of the second active pattern, wherein the second plurality of nanosheets spaced apart from the first plurality of nanosheets in the second horizontal direction;
a channel isolation layer extending in the first horizontal direction between the first active pattern and the second active pattern, wherein the channel isolation layer is in contact with a sidewall of each of the first plurality of nanosheets and the second plurality of nanosheets;
a gate electrode extending in the second horizontal direction on the upper surface of the first active pattern and the second active pattern, wherein the gate electrode surrounds the first plurality of nanosheets and the second plurality of nanosheets; and
a gate insulating layer between the gate electrode and the first plurality of nanosheets and between the gate electrode and the channel isolation layer, wherein a sidewall of a lowermost nanosheet of the first plurality of nanosheets is in contact with the channel isolation layer,
wherein the channel isolation layer comprises
a first layer in contact with a sidewall of each of the first active pattern and the second active pattern and in contact with the sidewall of each of the first plurality of nanosheets and the second plurality of nanosheets, wherein the first layer defines a lower surface and sidewalls of the channel isolation layer, and
a second layer surrounded by the first layer, wherein a material of the second layer is different from a material of first layer.

13. The semiconductor device of claim 12, comprising:
a field insulating layer surrounding each of the first active pattern and the second active pattern on the substrate,
wherein the lower surface of the channel isolation layer is lower, in relation to the substrate, than an upper surface of the field insulating layer.

14. The semiconductor device of claim 12, wherein the channel isolation layer is between portions of the gate electrode in the second horizontal direction.

15. The semiconductor device of claim 12, wherein an uppermost surface of the first layer is higher, in relation to the substrate, than an upper surface of an uppermost nanosheet of the first plurality of nanosheets.

16. The semiconductor device of claim 12, wherein the gate insulating layer is spaced apart from the second layer.

17. The semiconductor device of claim 12, wherein the gate insulating layer is between an uppermost nanosheet of the first plurality of nanosheets and the second layer.

18. A semiconductor device comprising:
a substrate;
a first active pattern extending in a first horizontal direction on the substrate;
a second active pattern extending in the first horizontal direction on the substrate, wherein the second active pattern is spaced apart from the first active pattern in a second horizontal direction different from the first horizontal direction;
a third active pattern extending in the first horizontal direction on the substrate, wherein the third active pattern is spaced apart from the first active pattern in the second horizontal direction, and is spaced apart from the second active pattern in the first horizontal direction;
a first plurality of nanosheets spaced apart from each other in a vertical direction on an upper surface of the first active pattern;
a second plurality of nanosheets spaced apart from each other in the vertical direction on an upper surface of the second active pattern, wherein the second plurality of nanosheets are spaced apart from the first plurality of nanosheets in the second horizontal direction;
a third plurality of nanosheets spaced apart from each other in the vertical direction on the upper surface of the first active pattern, wherein the third plurality of nanosheets are spaced apart from the first plurality of nanosheets in the first horizontal direction;
a fourth plurality of nanosheets spaced apart from each other in the vertical direction on an upper surface of the third active pattern, wherein the fourth plurality of nanosheets are spaced apart from the second plurality of nanosheets in the first horizontal direction, wherein the fourth plurality of nanosheets are spaced apart from the third plurality of nanosheets in the second horizontal direction;
a first channel isolation layer extending in the first horizontal direction between the first active pattern and the second active pattern, wherein the first channel isolation layer is in contact with a sidewall of each of the first plurality of nanosheets and the second plurality of nanosheets;
a second channel isolation layer extending in the first horizontal direction between the first active pattern and the third active pattern, wherein the second channel isolation layer is spaced apart from the first channel isolation layer in the first horizontal direction;
a first gate electrode extending in the second horizontal direction on the first active pattern and the second active pattern, wherein the first gate electrode surrounds the first plurality of nanosheets and the second plurality of nanosheets; and
a second gate electrode extending in the second horizontal direction on the first active pattern and the third active pattern, wherein the second gate electrode surrounds the third plurality of nanosheets and the fourth plurality of nanosheets, wherein the second gate electrode is spaced apart from the first gate electrode in the first horizontal direction,
wherein the first channel isolation layer comprises
a first layer in contact with a sidewall of each of the first active pattern and the second active pattern and in contact with the sidewall of each of the first plurality of nanosheets and the second plurality of nanosheets, wherein the first layer defines a lower surface and sidewalls of the first channel isolation layer, and
a second layer surrounded by the first layer, wherein a material of the second layer is different from a material of the first layer.

19. The semiconductor device of claim 18, comprising:
a gate insulating layer between the first gate electrode and the first plurality of nanosheets and between the first gate electrode and the first channel isolation layer, wherein a sidewall of a lowermost nanosheet of the first plurality of nanosheets is in contact with the first channel isolation layer.

20. The semiconductor device of claim 18, wherein a width of the second plurality of nanosheets in the first horizontal direction is less than a width of the first plurality of nanosheets in the first horizontal direction, and
wherein a width of the fourth plurality of nanosheets in the first horizontal direction is less than a width of the third plurality of nanosheets in the first horizontal direction.
